(19) United States
(12) Patent Application Publication
(10) Pub. No.: US 2025/0384173 A1
(43) Pub. Date: Dec. 18, 2025

(54) BUILDING INFORMATION MODEL MANAGEMENT METHOD AND SYSTEM

(71) Applicant: NuForm BIM Oy, Helsinki (FI)

(72) Inventor: Tomi TUTTI, Helsinki (FI)

(21) Appl. No.: 18/970,640

(22) Filed: Dec. 5, 2024

Related U.S. Application Data
(60) Provisional application No. 63/659,511, filed on Jun. 13, 2024.

(51) Int. Cl. G06F 30/13

(52) U.S. Cl. CPC G06F 30/13

(57) ABSTRACT

Techniques for Extracting, Transforming and Loading of data (ETL) from a Building Information Model (BIM) to assist in the production and construction of a building are provided. All necessary BIMs including but not limited to electrical BIM, ventilation BIM, sewage BIM, plumbing BIM, waterline BIM, constructional BIM may be processed with the aforementioned ETL to arrive at a complete model for the building. The complete BIM may be indexed in a data warehouse. The indexed data can be used to produce a Bill of Quantities of building materials in some part of the building or for the entire building.

### TECHNICAL FIELD OF INVENTION

The invention relates to computerised Building Information Models stored in a memory medium. More particularly, the invention relates extracting, transforming, and loading of data from a Building Information Model to assist in the production and construction of a building.

### BACKGROUND

Digitalisation continues in the building construction industry.

Computerised Building Information Models (BIMs) are known from, for example U.S. Pat. No. 11,599,693. In this reservoir like reference, data is extracted from a 2D floor plan, and a machine learning model is used to identify wall boundaries of the plurality of rooms. This document is cited here as reference.

WO 2014/091302 discloses quantified quality analysis and benchmarking techniques for BIMs. This document is cited here as reference.

U.S. Pat. No. 11,776,245 discloses a computer-implemented method and system for providing a safety risk analysis for building construction based on a BIM. This document is cited here as reference.

As one can see BIMs have been analysed to determine quality and safety of building construction in the prior art.

Currently building construction is a technical field where experts from multiple technical fields co-operate in an often chaotic and sometimes dangerous work environment. Each expert typically has their own methodology in producing drawings or blueprints. For example, the different drawing or blueprint conventions used by an electrician company may differ markedly from the drawing or blueprint conventions used by a plumbing company. Interleaving these different drawings from different contractors is only possible by substantial human engineering effort.

Furthermore, even after interleaving multiple different drawings or plans by human engineering effort, the prior art bundle of data is often confused and there is difficulty in using it to advance any business process.

Also, most of the management work is done on the building site, where computer resources are difficult to arrange.

### SUMMARY

The invention under study is directed towards a system and a method for effectively managing blueprints and drawings from multiple different experts on the building site. This is achieved by a cloud server network architecture that uses computerised search and artificial intelligence efficiently also in a mobile terminal, cloud server system. This allows the processing of very complex and detailed building information models, but also provides a very small administrative labour threshold to make changes to the building information model.

A further object of the invention is to present a system and a software product that allows to use the building information model in different building development tasks. These tasks include for example building material purchases and building permit applications. It is an object of the invention to enable the real time surveillance of the construction project to granular detail in time, steps, materials, finances and the like.

In one aspect of the invention, an architectural building information model, produced by an architect is extracted, transformed, and loaded (ETL abbreviated), into a data table or a data file. Then a subsequent building information model (BIM abbreviated), for example a plumbing BIM is ETL'ed to the data table or data file. Two BIMs are now combined in the data table or data file. Then the BIM geometry is divided into cubes. The quantities of material in the cubes are calculated. This data is stored in a data file or data table. Then this data is ETL'ed to a data warehouse. In the data warehouse, the building information data (two BIMS combined, divided in the cube grid) is indexed based on the coordinates in the divided cube. That is, a physical object represented in the data will have coordinates of a divided cube.

As the two BIMS may say the same thing in different words or units, in one aspect of the invention a deterministic rule-based synonym classifier is used in the ETL. For example, “centimeters” and “cm” could be both changed to “cm”. After the rule-based processing of data some data fields will still be unprocessed or deviating from the data warehouse format. These data fields are typically processed with an artificial intelligence model, such as Word2Vec or a neural network in the ETL process.

According to one aspect of the invention, all necessary BIMs including but not limited to electrical BIM, ventilation BIM, sewage BIM, plumbing BIM, waterline BIM, constructional BIM may be processed with the aforementioned ETL to arrive at a complete model for the building, the complete BIM, indexed the data warehouse.

The complete BIM indexed in the data warehouse could be, for example used in the procurement of the building materials (Bill of Quantities).

Some or all of the aforementioned advantages of the invention are accrued with a method used in a computer system for managing building information that is characterised by the following steps,
extracting and loading a primary design discipline building information model (BIM) to data tables and/or data files,
extracting and loading one or more subsequent building information models for the building to data tables and/or data files respectively,
dividing the building information model object geometry into sections, resolving sections for the divided objects, and calculating quantities of the divided geometry,
from the data tables and/or data files, extracting, transforming, and loading the data to a data warehouse,
harmonizing building storey definitions in each subsequent building information model to match the primary design discipline building information model,
indexing building information object and quantity data in the data warehouse at least based on the building identifier, storey identifier, section identifier and/or material layer set vector.

A system in accordance with the invention comprises a computer and is characterised in that,
extracting, and loading of a primary design discipline building information model (BIM) is configured to data tables and/or data files,
the extracting and loading of one or more subsequent building information models for the building is configured to staging data tables and/or data files respectively,
the building information model object geometry is configured to be divided into sections, section is configured to be resolved for divided objects and quantities of the divided geometry are arranged to be calculated,
from the data tables and/or data files the data is configured to be extracted, transformed, and loaded to a data warehouse,
building storey definitions in each subsequent building information model are configured to be harmonized with the primary design discipline building information model,
indexing building information object and quantity data in the data warehouse at least based on the building identifier, storey identifier, section identifiers and/or material layer set vector.

A software program product in accordance with the invention is stored in a memory medium configured to run in a computer system for managing building information, and is characterised by,
extracting and loading a primary design discipline building information model (BIM) for a building to staging data tables and/or data files,
extracting and loading one or more subsequent building information models for the building to data tables and/or data files respectively,
dividing the building information model object geometry into sections, resolving sections for the divided objects and calculating quantities of the divided geometry,
from the data tables and/or data files, extracting, transforming, and loading the data to a data warehouse,
harmonizing building storey definitions in each design discipline's building information model to match primary design discipline building information model,
indexing building information object and quantity data in the data warehouse at least based on the building identifier, storey identifier, section identifier and/or material layer set vector.

In some embodiments data transformations are not required when the BIM is loaded, so only extraction and loading steps take place in the first two ETL stages.

In one aspect of the invention there is a business intelligence or analytics software such as Microsoft Synapse that processes the data warehouse contents into a relational database. This analytics software may also call AI modules to complete tasks.

The invention has multiple technical and commercial advantages. The invention allows the property developer of the building to manage multiple different teams from different areas of engineering to produce a high-quality building with a small administrative overhead. Furthermore, with experience each BIM can be further refined and reused in a different building site to produce a similar, but even better building. These are substantial advantages that lead to higher quality and lower cost buildings to consumers in the marketplace.

Additionally, the invention can be used to predict unprofitable projects. when a sufficiently detailed building information model is in the system, and the developer has an accounting software with accurate prices, the system can linearly project, or predict using AI, the cost of the building. Based on the predictions, the developer can avoid unprofitable projects early on, for example at the Request for Quote stage. In some embodiments the so-called S-curve, which tracks the daily cost versus time is analysed to determine the profitability of the construction project. The invention can be used by property owners, property developers, maintenance companies, building design companies, architects, construction crews, Design and Build project crews and many more professionals in the building industry.

In addition, and with reference to the aforementioned advantage accruing embodiments, the best mode of the invention is considered to be a cloud-based server-client terminal system where a light client terminal, for example a Microsoft Surface tablet comprises the client software that is capable of combining BIMs and uploading them to the cloud server. Also, in the best mode the client terminal can typically do rule based ETLs, and simple AI based ETLs. However, the continuous updating and maintaining of the rules in the rule-based library is carried out at the server side. Similarly, the updating and retraining of the AI models is carried out server side. This has the advantage that machine learning acquired at one building site can be recycled to another building site by the cloud server network. In the best mode, typically the floor levels are calculated deterministically from the sea level for all building models of different contractors to determine common floor levels in the Z-coordinate. Typically, also material layer sets are calculated by using an AI model that simulates the material layer set as if the individual layers were words, and the material layer set was a sentence in the best mode. This way the AI technology developed for semantic models can be readily leveraged to calculate floors, walls and ceilings correctly in the best mode of the invention.

### BRIEF DESCRIPTION OF THE DRAWINGS

In the following the invention will be described in greater detail with reference to exemplary embodiments in accordance with the accompanying drawings, in which:

FIG. 1 demonstrates a basic embodiment 10 of the inventive method as a flow diagram.

FIG. 2 demonstrates a basic embodiment 20 of the inventive system as a block diagram.

FIGS. 3A-3E demonstrates a basic embodiment 30 of the inventive software program product as a schematic software illustration, with user interface.

FIG. 4 demonstrates a more developed embodiment 40 of the inventive method as a flow diagram.

FIG. 5 demonstrates a more developed embodiment 50 of the inventive system as a block diagram.

FIGS. 6A-6E demonstrates a more developed embodiment 60 of the inventive software program product as a schematic software illustration, with user interface.

FIG. 7 demonstrates a more developed artificial intelligence embodiment 70 of the inventive method as a flow diagram.

FIG. 8 demonstrates a more developed artificial intelligence embodiment 80 of the inventive system as a block diagram.

FIGS. 9A-9E demonstrates a more developed artificial intelligence embodiment 90 of the inventive software program product as a schematic software illustration, with user interface.

FIG. 10 demonstrates a more developed data warehouse outcome embodiment 91 with or without artificial intelligence, of the inventive method as a flow diagram.

FIG. 11 demonstrates a more developed data warehouse outcome embodiment 92 with or without artificial intelligence, of the inventive system as a block diagram.

FIGS. 12A-12C demonstrates a more developed data warehouse outcome embodiment 93 with or without artificial intelligence, of the inventive software program product as a schematic software illustration, with user interface.

FIG. 13 demonstrates the best mode embodiment 94 of the inventive method as a flow diagram.

FIG. 14 demonstrates the best mode embodiment 95 of the inventive system as a block diagram.

FIG. 15 demonstrates the best mode embodiment 96 of the inventive software program product as a schematic software illustration, with user interface.

Some of the embodiments are described in the dependent claims.

### DETAILED DESCRIPTION OF EMBODIMENTS

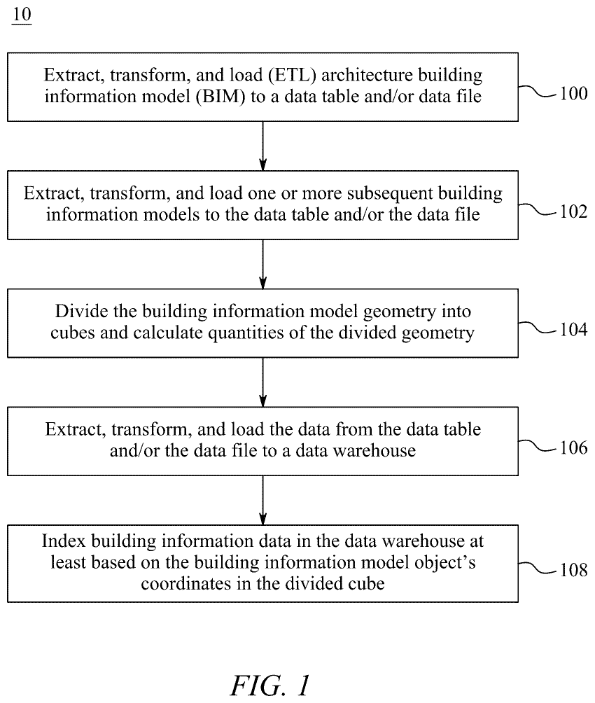

FIG. 1 shows the basic inventive method embodiment 10 as a flow diagram. In phase 100 the architecture building information model (BIM), which is typically the starting point for any new building is extracted, transformed, and loaded (ETL) into a data table typically in a database, or a data file. In some cases, a different BIM might be selected as a starting point. In some embodiments data transformations are not required, so only extraction and loading steps take place in phase 100. All in all, extracting and loading a primary design discipline building information model (BIM) to data tables and/or data files

A BIM typically has the plot of land as the main or root level hierarchy. At the same or subhierarchy level to the plot of land, come the buildings. At a yet lower hierarchy level still come the intra-building spaces and structures, like the living room, garage, main wall, bathtub, material layer set, material layer 1, material layer 2, building element assemblies and the like. Some BIMS may have the default assumption of having one plot of land and one building on that plot of land.

Subsequently, in phase 102 another building information model is extracted, transformed, and loaded similarly to a data table and/or data file. Subsequent building information models (BIM) may include but are not limited to: electrical BIM, ventilation BIM, sewage BIM, waterline BIM, constructional BIM, and these are loaded to their data tables and/or data files respectively. In some embodiments data transformations are not required, so only extraction and loading steps take place in phase 102. I.e. extracting and loading one or more subsequent building information models for the building to data tables and/or data files, respectively, takes place in phase 102.

When the BIMs are loaded, the data is sometimes stored in a temporary storage called a staging area in some embodiments. In some embodiments the data format of the BIM complies with IFC (Industry Foundation Classes) file format.

In phase 104 the building information model geometry is divided into cubes and quantities of the divided geometry are calculated. For example, a cube 3 meters by 3 meters by 3 meters might be selected, and the entire BIM be divided to cubes of this size. So, a building information model describing a building 30 meters heigh, 30 meters wide and 30 meters deep, would be divided to at least 10*10*10=1000 thousand cubes. Currently the cube is considered the best choice for the divided geometry, but this can be any shape. Thus, dividing the building information model object geometry into sections, resolving sections for the divided objects, and calculating quantities of the divided geometry takes place in phase 104.

Also, a different shape than a cube is possible in accordance with the invention in some embodiments. For example, a rectangle can be used. In some embodiments the BIM does not have defined floors, and in a high building the divided sections can be very high and thin rectangles indeed. These high and thin rectangles are occasionally referred to as location prisms.

In some embodiments of the invention, contractors typically divide the floors of a building into parts to be implemented. The sections go through the floors, that is, from the lowest floor of the building to the top.

In an apartment building, for example, the part to be implemented can consist of one staircase. In an office or commercial building, one part can be formed, for example, by one wing of the building. The floors of a building are typically divided into sections, because studies have shown that it is faster to complete one part at a time from bottom to top than to complete the entire floor at a time.

The implementation of the building consists of three main stages:
Foundation
Trunk
Interior manufacturing

Often the building is divided into “rough” parts for the foundation and frame phase, and more “subtle” parts for interior manufacturing. As a large number of operators are involved in interior manufacturing, it is more difficult to manage than the frame, which is why it is typically broken down into smaller parts.

In some embodiments of the invention, in the interior manufacturing version, the standard 3×3 m grid is replaced by space objects from the architectural model, which form the corresponding grid/cubes. The spaces objects typically come from the architect's building information model, because the building information models of other design disciplines do not normally have Space objects. With BIM Processing Unit, space objects from the architect's model are stored as BIM files in the staging area of the Data Warehouse. Spaces of the gross floor area type are typically not stored in the file, because objects would be chopped. Then again, a water and sewage BIM may also comprise drains that occur outside the building.

In phase 106 from the data table and/or data file with the divided geometry, data is extracted, transformed, and loaded to a data warehouse. The BIMs, data tables and/or data files, and the data warehouse are typically on a cloud service such as Microsoft Azure or Amazon AWS. However, the inventive method can be practiced in principle in any computer configuration, including a standalone computer. The locations are typically expressed in Cartesian X, Y, Z co-ordinates, but other co-ordinate systems are possible. In this stage also the different floors, and their locations are typically resolved, with a deterministic calculation and/or Artificial Intelligence. I.e. the locations of the different floors of a multi-story building are resolved in the Z-coordinate.

I.e. in phase 106 from the data tables and/or data files, extracting, transforming, and loading the data to a data warehouse and then harmonizing building storey definitions in each subsequent building information model to match the primary design discipline building information model results in data for the data warehouse, which is then indexed in phase 108.

In some embodiments the data warehouse is a relational database, which has database schemas suited for reporting. The data warehouse typically combines information from multiple BIMS. Also, in some embodiments the data warehouse stores the different versions of the different BIMs from different contractors, thereby maintaining temporal control of the BIMs as they are amended over time.

In some embodiments of the invention the data warehouse has three reportable entities: building spaces, building elements, and building element assemblies. These entities serve different functions in construction:

The Building spaces entity primarily serves the needs of the client of the construction project, as it can be used to analyse the project from a functional point of view.

Building elements, and specially Building elements assemblies, primarily serve the needs of the developer of the construction project. Building element assemblies typically consist of the foundation and frame parts of the building, which make up a significant part of the implementation. Building elements, on the other hand, include all parts of the building, i.e. in addition to the above, also the parts needed for interior preparation.

In some embodiments of the invention The Data Warehouse Bus architecture (or Enterprise Bus) developed by Ralph Kimball is used because it is suitable for situations such as those described above, where several processes share key dimensions. The inventive data warehouse can be combined to a bigger data warehouse.

Subsequently in phase 108, building information data, combining the multiple BIMs in the divided geometry in the data warehouse is indexed at least based on the building information model object's coordinates in the divided cube or section. I.e. an index is created including the location of each divided cube or section in the building, and also the locations of different objects such as wall, window, door or the like, within each respective cube. The locations can be expressed in Cartesian X, Y, Z coordinates, but other coordinate systems are possible. The most practicable indexing method is typically the indexing of the object and quantity data in the data warehouse at least based on the building, storey and section identifiers.

Any features of the basic embodiment 10 may be readily combined or permuted with any of the other embodiments 20, 30, 40, 50, 60, 70, 80, 90, 91, 92, 93, 94, 95 and/or 96.

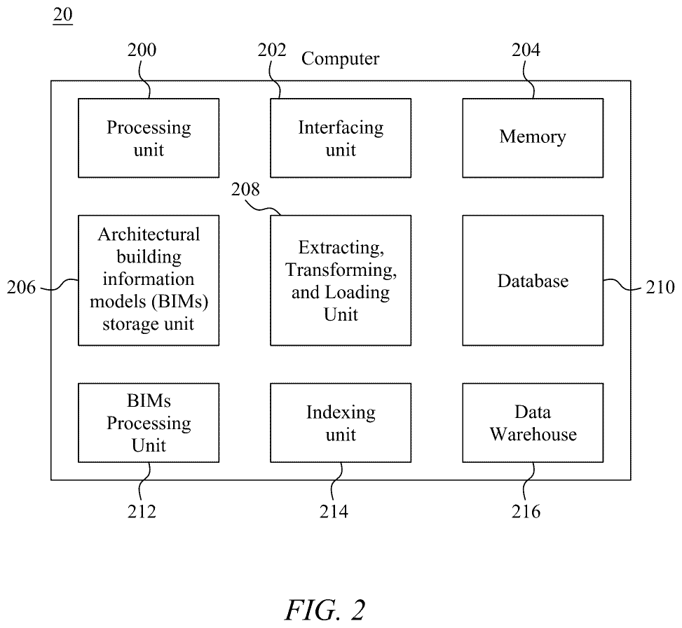

FIG. 2 discloses a basic embodiment 20 of the system carrying out the invention on a single standalone computer. The system 20 may be configured as a mobile terminal computer, typically a tablet or a PC that is used to manage tasks of the user by operating software applications. The computer 20 is typically a Windows or Linux PC.

The processing unit 200 is typically a CPU or a GPU 206 or is present in the computer 20.

Processing unit 200 may include any one or more microprocessors, finite state machines, computers, microcontrollers, digital signal processors, logic, a logic device, an electronic circuit, an application specific integrated circuit (ASIC), a field-programmable gate array (FPGA), a chip, etc., or any combination thereof, capable of executing computer programs or a series of commands, instructions, or state transitions. The processing unit may also be implemented as a processor set comprising, for example, a general-purpose microprocessor and a math or graphics co-processor. The processor may be selected, for example, from the Intel® processors such as the Itanium® microprocessor or the Pentium® processors, Advanced Micro Devices (AMD®) processors such as the Athlon® processor, UltraSPARC® processors, microSPARC™ processors, HP® processors, International Business Machines (IBM®) processors such as the PowerPC® microprocessor, the MIPS® reduced instruction set computer (RISC) processor of MIPS Technologies, Inc., RISC based computer processors of ARM Holdings, Motorola® processors, etc. The GPU refers to an electronic circuit designed to manipulate and alter computer graphics, images, and memory to accelerate the analysis and creation of images/patterns. GPUs are used in embedded systems, mobile phones, personal computers, workstations, game consoles, etc. The GPU may be selected, for example, from AMD GPUs, Nvidia GPUs, Intel GPUs, Intel GMA, Larrabee, Nvidia PureVideo, SoC, etc. In the invention, preferentially the machine learning parts of the processing are configured to be executed by the GPU, due to the large number of parallel processing or comparative processing required in machine learning.

It is also possible that the system 20 is a mobile station, a computer, such as a PC-computer, Apple Macintosh-computer, PDA-device (Personal Digital Assistant). The system 20 could further be a device having software or an operating system such as any of the following: Microsoft Azure, Microsoft Windows, Windows NT, Windows CE, Windows Pocket PC, Windows Mobile, Palm OS, Meego, Mac OS, Linux or any other computer or tablet operating system.

The memory 204 includes a computer readable medium. A computer readable medium may include volatile and/or non-volatile storage components, such as optical, magnetic, organic, or other memory or disc storage, which may be integrated in whole or in part with a processor, such as processor. Alternatively, all or part of the entire computer readable medium may be remote from processor and coupled to processor 204 by connection mechanism and/or network cable. In addition to memory 204, there may be additional memories that may be coupled with the processor or the GPU of the Processing Unit 200. The interfacing unit 202 is typically the keyboard, screen, mouse, and any other devices with which the user controls and uses the computer.

The extracting, transforming, and loading (ETL) unit 208 is a software module that takes the architectural building information model (BIM) as input and extracts, transforms, and loads data from it to a data table, typically in a database 210 and/or data file, typically in memory 204.

The BIM processing unit 212 then takes in additional BIMs of one or more subsequent building information models, such as a plumbing building information model, to the data tables in the database 210 and/or into the data files in the memory 204. Typically, the BIMs are kept in separate files or data tables, and combined from these files to yield the combined BIM. BIMs are typically stored in a document bank, such as MS SharePoint or the like, or in some other database or cloud-based storage such as Autodesk Construction Cloud or Trimble Connect, or as files, for example using SimpleBIM software.

The BIMs are typically viewed for operational purposes, and sometimes the database schema is different to the data storage, which in turn stores data for reporting purposes, as opposed to operational purposes.

The combined building information model geometry is divided into sections or cubes by the BIMs processing unit 212 and quantities of the divided geometry are calculated. The combined BIM with the divided geometry from the data tables and/or data files is extracted, transformed, and loaded to a data warehouse 216. The indexing unit 214 indexes the combined BIM data in the data warehouse 216 at least based on the building information model object's coordinates in the divided cubes.

Any features of embodiment 20 may be readily combined or permuted with any of the other embodiments 10, 30, 40, 50, 60, 70, 80, 90, 91, 92, 93, 94, 95 and/or 96.

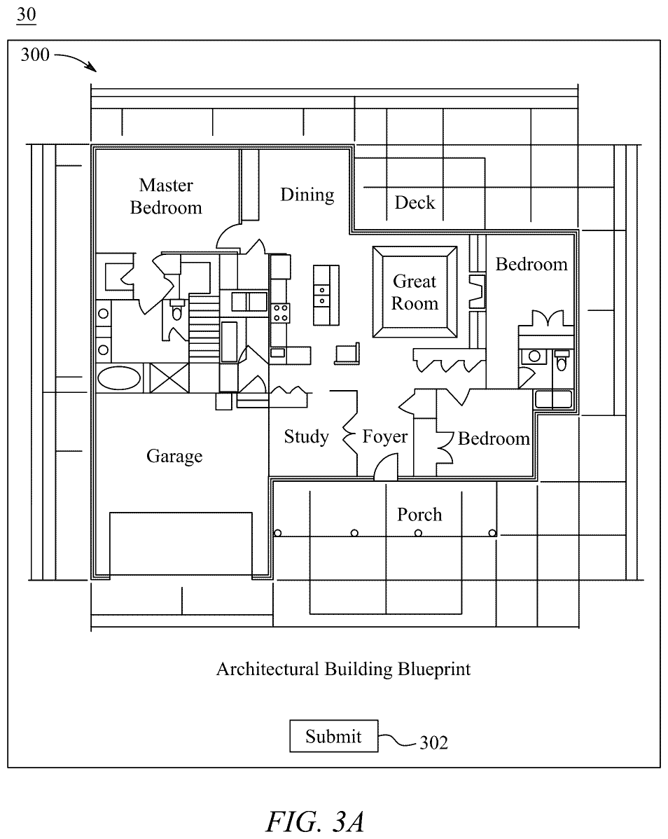

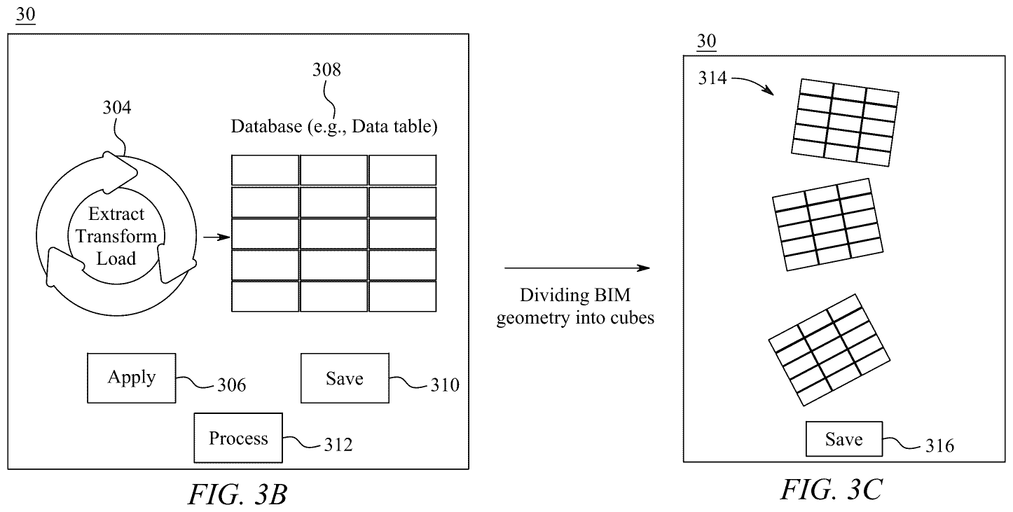

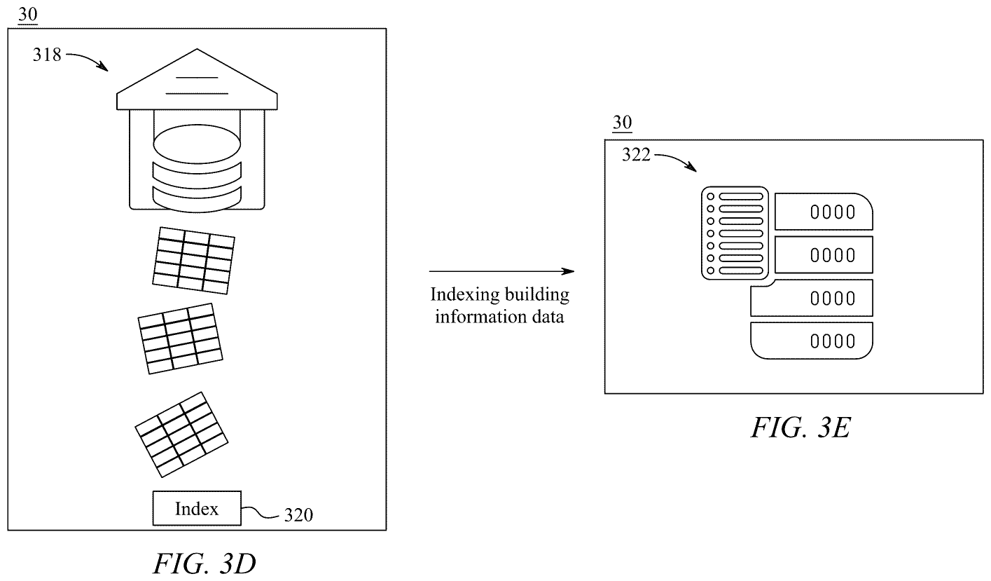

FIG. 3 shows an embodiment 30 of a software program product of the invention, which is stored in a memory medium 204 configured to run in a computer system 20 for managing building information. In FIG. 3A an architectural plan displayed on the basis of an architectural BIM is shown. In FIG. 3B the architectural BIM is extracted, transformed, and loaded (ETL) to a data table and/or data file in accordance with how the user controls the software using toggles 306, 310, 312. One or more subsequent building information models, such as electricity blueprint, can be similarly ETL'ed 304 to data table and/or data file, resulting in a combined BIM in a database or data file. FIG. 3C shows the dividing of the combined building information model geometry into cubes and the calculation of quantities of the divided geometry.

FIG. 3D shows the combined BIM data table and/or data file contents being extracted, transformed, and loaded to a data warehouse 216. A shown in FIG. 3E, the combined building information data in the data warehouse is indexed at least based on the building information model object's coordinates in the divided cubes. This makes the combined BIM searchable, and allows for example to build or procure building materials one cube of the building at a time.

Any features of embodiment 30 may be readily combined or permuted with any of the other embodiments 10, 20, 40, 50, 60, 70, 80, 90, 91, 92, 93, 94, 95 and/or 96.

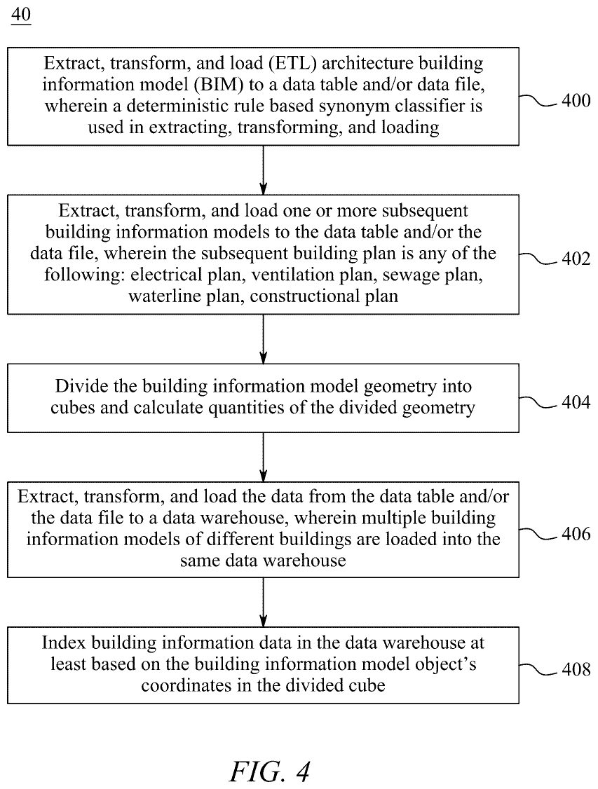

FIG. 4 shows embodiment 40 where the invention is working on a slightly larger scale than in embodiment 10 with simple data manipulation operations. In phase 400 a deterministic rule-based synonym classifier is used in extracting, transforming and/or loading an architecture BIM. This means that if for example the data warehouse and other subsequent BIMs use “cm” to signify centimeters as the unit of length, a term “centimeter” would be converted to “cm” as the classifier defines a rule that “cm” and “centimeter” are synonymous.

In phase 402 subsequent BIMs, typically all BIMs needed to complete the building are ETL'ed to the data table and/or the data file, just like the architectural BIM was in phase 400. These BIMs may include but are not limited to: the electrical BIM, ventilation BIM, sewage BIM, waterline BIM, construction BIM. As a consequence, the data table and/or data file now has a universally understood combined BIM with harmonised and consistent nomenclature and units.

In phase 404 the combined BIM with harmonised nomenclature and units is divided into cubes and quantities of building materials or objects in each cube of the divided geometry are calculated.

In phase 406 the combined divided BIM with harmonised nomenclature and units is ETL'ed to a data warehouse. Additionally, the similarly combined divided BIMs of other buildings with harmonised nomenclature are also loaded to the same data warehouse.

We will look at one deterministic transformation in accordance with the invention here, namely the assignment of correct floor numbers across all BIMs. Each building information model for different design disciplines typically includes its own floor specifications, and they may conflict with each other. In a data warehouse, the building floors must be unambiguous, so the layer data of the objects in the building information models of different design disciplines must be harmonised. In addition, in the data warehouse, the floors of different buildings must also be “coded” and, for reporting, named in a uniform manner.

The floor data of the building and the objects it contains can be classified as follows: Choose the one from the design discipline that works in the primary design discipline role. This is typically, architecture, but can be something else. The choice can be a build-level or system-level setting in some embodiments.

The primary design discipline, architecture in phase 400, BIM (PDD BIM) serves as a source of floor elevation positions. The floor numbers are formed by comparing the elevation of the plot and the elevation stations of the floors in the PDD data model, so that the floor closest to the height of the plot gets the number 0 and the other floors are numbered relative to this floor.

Objects in PDD data models and other design models have been set to specified parameters required for layer calculations, such as object reference height.

The layer numbers of objects in the PDD data model and other design disciplines are formed by comparing the reference height of the object with the heights of the different layers and selecting the layer that is closest to the object.

The building information model building site object contains information about the elevation of the plot compared to sea level. Similarly, building storey objects in the building information model have information about their elevation from sea level. By utilising this information, the layers can be classified, i.e. they can be given standard floor numbers and, if desired, these floors can be given names.

What all possible buildings have in common is that they have a floor at ground level. So, the task is to identify which layer is at ground level.

The first step is to choose which building's building information model will provide the floor elevation positions, this is usually the Primary Design Discipline (PDD), which is usually the architecture model. An architect's building information model typically plays this role, but the field of design can also be another.

After that, for each layer of the PDD data model, its distance from the surface of the plot is calculated. For the layer with the absolute value of the distance, the layer number is set to 0. Layers in elevation higher than the zero floor get numbers 1, 2, 3, etc. by elevation position in increasing order. Downwards, the layers get the numbers —1, −2, −3, etc. by floor height in descending order.

In some embodiments the 3D geometry of objects may be inaccurate for various reasons, which is why a tolerance used in layer calculations is set for all objects together or separately. Tolerance is used when layers are divided into those below and above an object. For example, in the case of a tile, a layer slightly below its upper surface would be accepted as the overhead layer.

In phase 408 the combined BIMs of multiple buildings are indexed. The index is based at least on the cube and its location. Therefore, any material or object can be located by the cube it is in, and by the coordinate location that it has within that cube.

Any phases or features of embodiment 40 may be readily combined or permuted with any of the other embodiments 10, 20, 30, 50, 60, 70, 80, 90, 91, 92, 93, 94, 95 and/or 96.

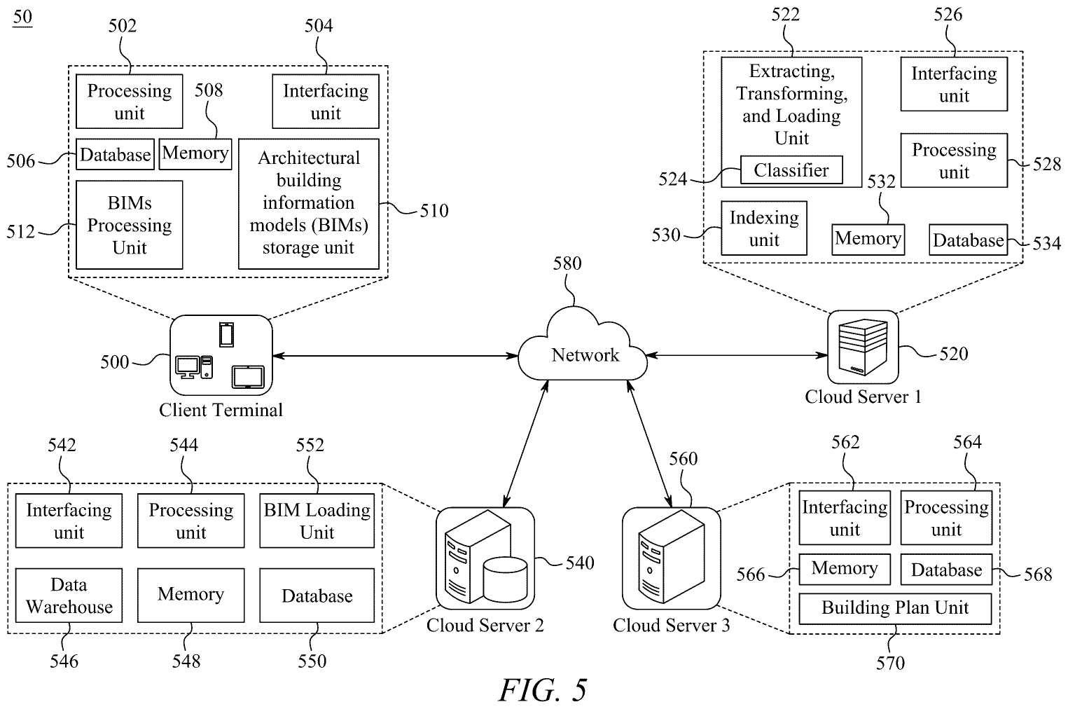

FIG. 5 shows a system embodiment 50 of the invention with a cloud server, which is accessed from the client terminal 500 via a communication network 580. One or more cloud servers 520, 540, 560 may comprise one or more GPUs.

The communication network 580 used for the communication in the invention is the wireless or wireline Internet or the telephony network, which is typically a cellular network such as UMTS—(Universal Mobile Telecommunication System), GSM—(Global System for Mobile Telecommunications), GPRS-(General Packet Radio Service), CDMA—(Code Division Multiple Access), 3G-, 4G-, 5G Wi-Fi and/or WCDMA (Wideband Code Division Multiple Access)-network.

In some embodiments the client terminal 500 is Internet browser based, and in this embodiment BIMs Processing Unit 512, BIM storage unit 510, database 506 are not necessarily required.

In an example, the cloud server may comprise a plurality of servers 520, 540, 560. In an example implementation, the cloud server may be any type of a database server, a file server, a web server, an application server, etc., configured to store data related to BIMs and/or other applications. In another example implementation, the cloud server may comprise a plurality of databases for storing data files. The databases may be, for example, a structured query language (SQL) database, a NoSQL database such as the Microsoft® SQL Server, the Oracle® servers, the MySQL® database, etc. The cloud server may be deployed in a cloud environment such as Microsoft Azure or Amazon AWS, and be managed by a cloud storage service provider, and the databases may be configured as cloud-based databases implemented in the cloud environment.

The cloud server 520, 540, 560 which may include an input-output device usually comprises a monitor (display), a keyboard, a mouse and/or touch screen. However, typically there is more than one computer server in use at one time, so some computers may only incorporate the computer itself, and no screen and no keyboard. These types of computers are typically stored in server farms, which are used to realise the cloud network used by the cloud server of the invention. The cloud server can be purchased as a separate solution from known vendors such as Microsoft and Amazon and HP (Hewlett-Packard). The cloud server typically runs Unix, Microsoft, iOS, Linux, or any other known operating system, and comprises typically a microprocessor, memory, and data storage means, such as SSD flash or Hard drives. To improve the responsiveness of the cloud architecture, the data is preferentially stored, either wholly or partly, on SSD i.c. Flash storage. This component is either selected/configured from an existing cloud provider such as Microsoft or Amazon, or the existing cloud network operator such as Microsoft or Amazon is configured to store all data to a Flash based cloud storage operator, such as Pure Storage, EMC, Nimble storage or the like. Using Flash as the backbone storage for the cloud server is preferred despite its high cost due to the reduced latency that is required and/or preferred for retrieving user data, user preferences, and data related to BIMs, applications etc.

Computing tasks may be split in any convenient division between terminal and server side, considering latency and performance of either terminal or server device in the given environment.

In embodiment 50 a deterministic rule-based synonym classifier is used in extracting, transforming and/or loading (ETL) of any BIM. This may happen immediately on the terminal device 500, or any cloud server 520, 540, 560. The BIM may be but is not limited to being any of the following: architectural plan, electrical plan, ventilation plan, sewage plan, waterline plan, constructional plan. Typically, the classifier operates by means of deterministic tables wherein a certain range of different words or units is translated and converted to a specified one. For example, “conc.” (known acronym of concrete) and “C35” (a type of concrete) could both be converted to “concrete”. This ensures that the different BIMs from different contractors such as plumber, electrician, structural designer and so forth provide specification with uniform nomenclature and units.

Using the deterministic rule-based synonym classifier also enables multiple building information models of different buildings being loaded into the same data warehouse with uniform nomenclature and units being used for all buildings.

In the following more detailed exemplary implementations of the system parts are described. Data Warehouse 856 is typically a relational database with database schema optimized for reporting. Examples could include SIM. Star Schema or Snowflake Schema. Data warehouse 856 typically combines information from multiple sources, in this case, BIMs from applications in various design disciplines, such as architectural, plumbing, electric and the like. Data warehouse 856 typically contains temporal data (e.g. current situation vs. history). For example, the different versions of the building information models of different design disciplines are updated every 2-4 weeks during the design and construction phase.

In one inventive implementation alternative, building information models from several different design disciplines in one building and their different versions can be assembled into one “bundle” in the data warehouse 856. The data produced by the first ETL phase 1 400, 402 will be recompiled in the second ETL phase 406. When recompiling, the hierarchical (operational) IFC schema of the data model is converted to the schema used by the data warehouse 856 (reporting). Typically, the data model will have the same timestamp for all objects. This is the previously mentioned data warehouse 856 temporal data. The board will typically contain other information in addition to the above, such as the name and address of the building. The BIM Processing Unit 512 “owns” this table and through it e.g. adds new buildings to the board.

Other database tables are “owned” by the Extracting, Transforming and Loading Unit 522, i.e. it adds, updates, etc. data to other tables in data warehouse 546.

In some embodiments of the invention the data warehouse 856 has a staging area. This is a temporary data storage location between data source and data warehouse 856. In this case, the temporary storage location is between the Bim Processing Unit 512 and the Data Warehouse 856.

Two different formats for storing data can be utilised in accordance with the invention: Data tables or data files.

In the case of data tables there are several data tables per one design discipline. Below are the exemplary data tables for the architectural BIM:
Buildings—architectural
Building spaces—architectural
Space data is generated only from the architect's model
Building elements—architectural
Building element materials—architectural
Building element assemblies—architectural

Preferably the following tables are produced only from the primary design field, which is architecture model here:
Building site
Building storeys.

The primary choice of design field can be, for example, system or building level setting in the software. Data tables typically always have columns for BUILDING_ID and UPLOAD_DATETIME to signify the building identity, and the upload time, respectively.

In some embodiments data files are stored in a folder structure that corresponds to the data tables in the staging area. At the beginning of the second ETL, the contents of each file are added by the Extracting, Transforming and Loading Unit 522 to the corresponding database table in the Data Warehouse 856 Staging Area, and then deleted. When adding, DW_BUILDING_ID (storing building ID) and DW_UPLOAD_DATETIME (storing date and time) variables are moved from the file name of the data file to data table column data in some embodiments.

In some embodiments, the BIM Processing Unit 512 is responsible for the first ETL step 400, 402, i.e. the flow of information from the user's BIM to DW's staging area. The first ETL typically reads the Building Information Model into the program and reads the 3D geometry and non-geometric data fields of objects into the program. The BIM Processing Unit 512 also typically writes non-geometric data from the BIM to the data warehouse 856 staging area. Non-geometric data can include data derived (calculated) from 3D geometry, the best example of which is quantities of materials.

Extract, Transform and Load Unit 522 is typically an enterprise-level software whose main purpose is to build data warehouses, such as data warehouse 856.

Extract, Transform and Load Unit 522 software provides advanced features for it, such as integration with machine learning environments.

Database 550, 568 is typically a Relational database, for example a Microsoft SQL Server. In some embodiments of the invention, the data warehouse 856 is located in a database, but for security reasons, users usually cannot access the database directly. Interfacing Unit 562 is typically a software between the database and users that provides a secure data transfer interface for 3rd party applications.

The computer systems of the invention typically also comprise file storage which allow to set up folders for files, store BIM files to be uploaded, and can be used as a data warehouse 856 staging area file storage. The staging area is typically a temporary storage location:→the files are deleted from the staging area when they are no longer needed in some embodiments.

Any features of embodiment 50 may be readily combined or permuted with any of the other embodiments 10, 20, 30, 40, 60, 70, 80, 90, 91, 92, 93, 94, 95 and/or 96.

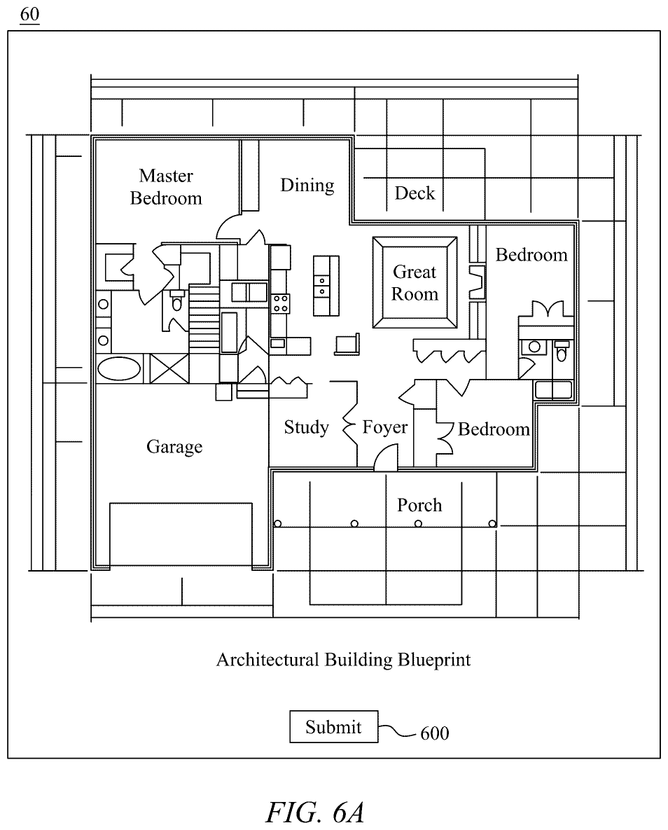

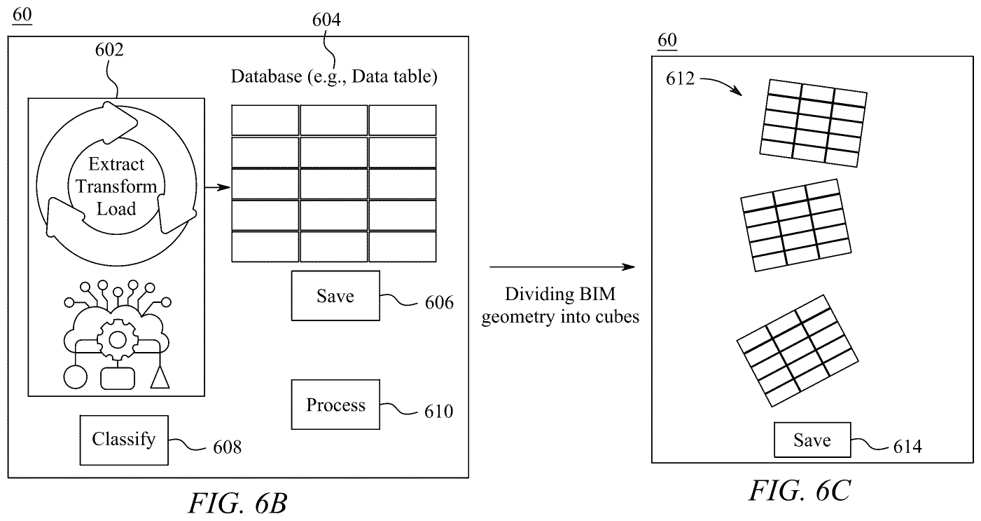

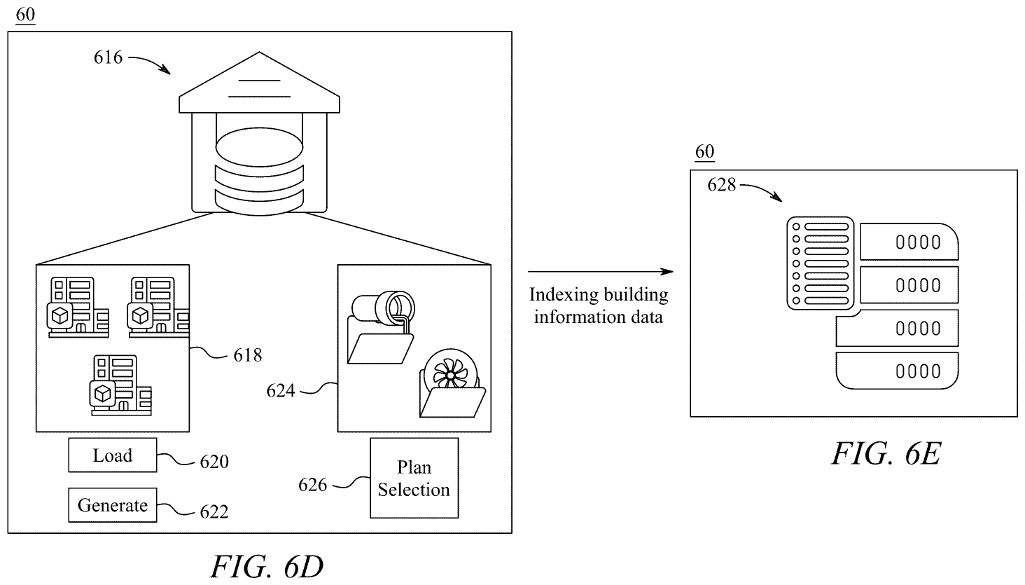

FIG. 6 shows an embodiment 60 of the software program product that operates the method 40 with the system 50 of the invention. In FIG. 6A an architectural plan is displayed. An architectural BIM underlies the displayed plan. FIG. 6B shows there is a deterministic rule-based synonym classifier 608 used in the extracting, transforming and/or loading of the architectural BIM, and any other subsequent BIM, such as plumbing BIM electrical plan, ventilation plan, sewage plan, waterline plan, constructional plan, or the like.

FIG. 6C shows how the combined BIM sufficient to produce the building is divided into cubes. The combined BIM with the divided geometry is loaded to a data warehouse as shown in FIG. 6D.

In FIG. 6D multiple building information models of different buildings 618 are also loaded into the same data warehouse, which may be of different types such as ventilation and plumbing as shown in toggle 624. This has the added benefit that the data warehouse can be used to manage multiple buildings in some embodiments. The different building information models can be selected by using the plan selection 626 button.

FIG. 6E shows that the BIMs of all these buildings are indexed based on the divided cube geometry. The contents of each cube, and the location of those contents within that cube are thus searchable by the index. It is also possible that indexing building information object and quantity data in the data warehouse is at least based on the building, storey and section identifiers (108, 408, 714).

Any features of embodiment 60 may be readily combined or permuted with any of the other embodiments 10, 20, 30, 40, 50, 70, 80, 90, 91, 92, 93, 94, 95 and/or 96.

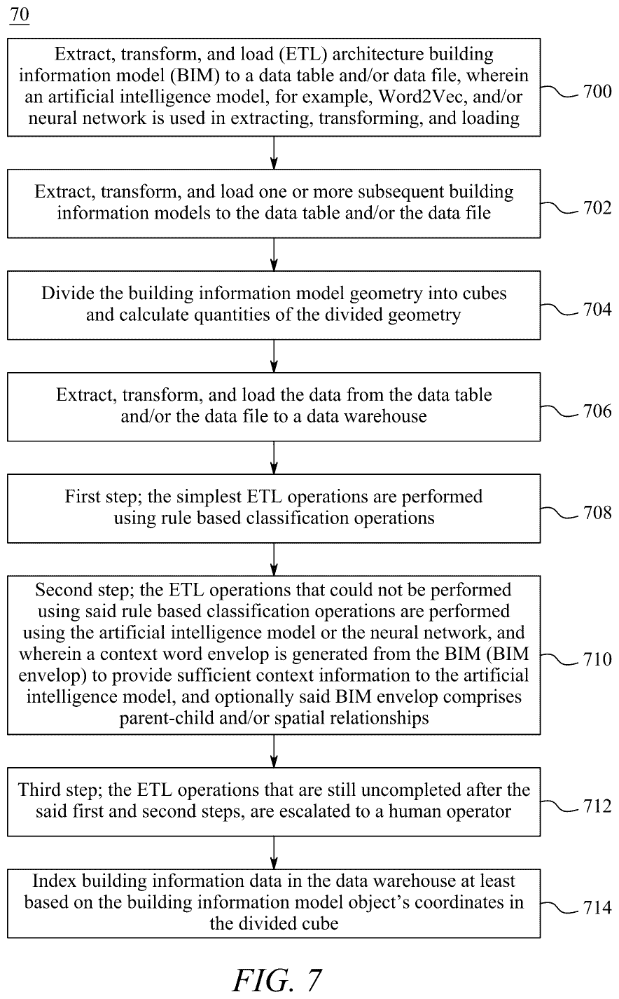

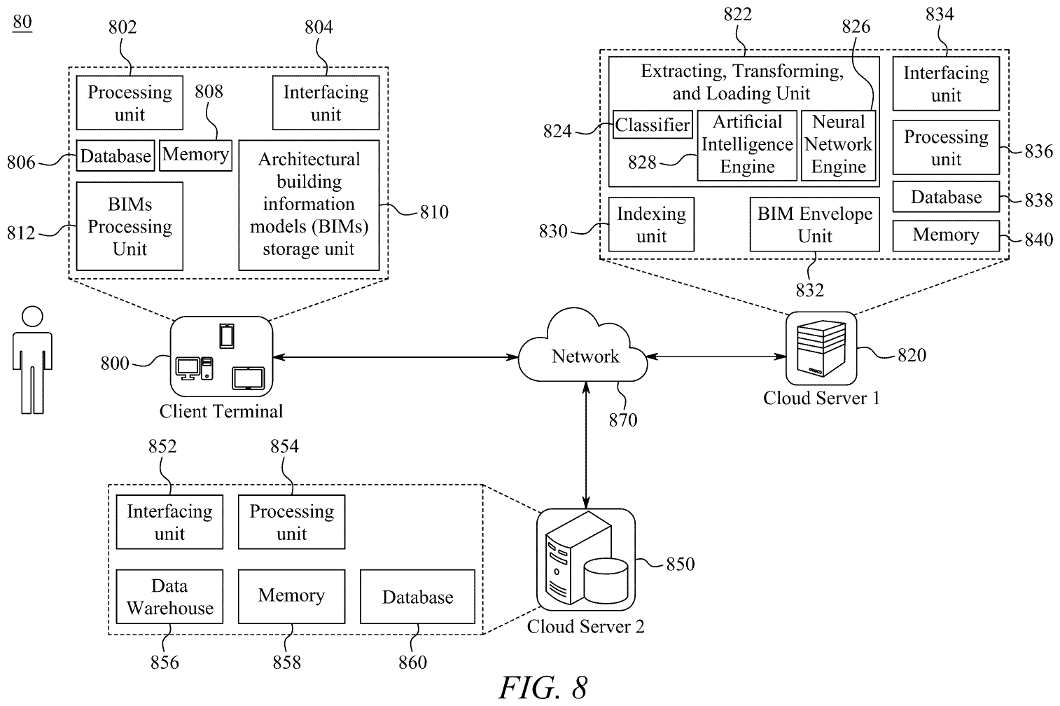

FIG. 7 shows the embodiment 70 where the combined BIM is produced using AI techniques. In phase 700 known machine learning tools/deep learning frameworks may be utilized with or without modifications to ETL the architecture BIM into a data table or data file.

A few such known machine learning tools comprise Caffe™, Api.ai™, TensorFlow™, Mahout™, OpenNN™, H20™, MLlib™, NuPIC™, OpenCyc™, Oryx 2™, PredictionIO™, SystemML™, TensorFlow™, and Torch™. Preferably, an artificial intelligence model, for example Word2Vec, and/or neural network is used in extracting, transforming, and loading in phase 700. Subsequently in phase 702 the same treatment is given to other BIMs, such as the electrical BIM or plumbing BIM or the like.

In phase 704 the combined BIM geometry, compiled using AI, is divided into cubes, and building material quantities within the cubes are calculated.

In phase 706 the ETL of the combined BIM with divided geometry to the data warehouse begins.

In phase 708 first step; the simplest ETL operations are performed using rule-based classification operations. These operations typically require a light processing load from the computer system, and therefore it is preferential to arrive at a rule-based outcome for all data fields where a rule-based outcome is possible.

In phase 710 second step; the ETL operations that could not be performed using said rule-based classification operations are performed using an artificial intelligence model and/or a neural network. These operations typically require a greater processing load than rule-based operations. In one embodiment, a context word envelope is generated from the BIM (BIM envelope) to provide sufficient context information to the artificial intelligence model, and optionally said BIM envelope comprises parent-child and/or spatial relationships, which can be used to predict how a yet unrecognised data field should be converted.

In phase 712—third step; the ETL operations that are still uncompleted after the said first and second steps of phases 708, 710, are escalated to a human operator, who may manually re-enter the data field in the desired format.

The first 708, second 710 and the third 712 steps may also be implemented in the ETL processes of 700, and 702 with any BIM in some embodiments.

In phase 714 the three-step processed combined BIM with divided geometry is indexed so that any material or object may be located based on the cube it is in, and the co-ordinate location within that cube.

Any features of embodiment 70 may be readily combined or permuted with any of the other embodiments 10, 20, 30, 40, 50, 60, 80, 90, 91, 92, 93, 94, 95 and/or 96.

FIG. 8 shows a system diagram where method embodiment 70 just explained could be carried out.

The client terminal 800 is capable of using an artificial intelligence model, for example Word2Vec, and/or neural network in the extracting, transforming, and loading ETL of one or more BIMs. As a first step, the simplest ETL operations are performed using rule-based classification operations on the terminal device 800. So, For example, “conc.” (known acronym of concrete) and “C35” (a type of concrete) could both be converted to “concrete”. However, a problem may arise with “concret”, which is just a misspelling of “concrete”, and therefore “concret” is unlikely to be present in any deterministic table of synonyms for “concrete”, where “C35” and “conc.” would be present.

Then, as a second step; the ETL operations that could not be performed using said rule-based classification operations are performed using an artificial intelligence model or a neural network on the client terminal 800. In this situation of “concret”, for example a natural language learning model could be used to identify that “concret” is a misspelled “concrete” word. Therefore, this AI model would substitute “concret” with “concrete”. To facilitate this, in some embodiments a context word envelope is generated from the BIM (BIM envelope) to provide sufficient context information to the artificial intelligence model, and optionally said BIM envelope comprises parent-child and/or spatial relationships of different construction elements or objects in the BIM.

As a third step, the ETL operations that are still uncompleted after the said first and second steps, are escalated to a human operator who uses the client terminal 800.

However, all or some parts of the ETL processing could also be distributed to any of the cloud servers 820, 850, network 870 permitting.

In one aspect of the invention there is a business intelligence or analytics software such as Microsoft Synapse that processes the data warehouse 856 contents into a relational database 860. This analytics software may also call AI modules to complete tasks.

Artificial Intelligence Engine 828 is typically a Machine Learning Unit that runs software for training, inferring and developing machine learning models. Examples of which are Word2vec, Azure Machine Learning and different neural networks.

The Building space, element and element assembly, as well as the class of other objects in the BIM, is perhaps the single most important piece of information. In the case of a building element, the class indicates whether it is, for example, an external building element or internal partition. This is important information because the construction process is very much organized according to these classifications.

As an example, let's use a building element with data fields shown as in the below:

| ID | 1234567890 | |
|---|---|---|
| DW object class | ??? → The end result should be an Internal wall | |
| Storey | 3 | |
| BIM object class | Wall | |
| Class hint | Int. wall gypsum 110 mm | |
| Load bearing | Well | |
| External/internal | External | |
| Shape factor | 0.52 | |
| Material layer set | | |
| Material layer 1 | Gypsum board | 13 mm |
| Material layer 2 | Insulation + aluminium studs | 80 mm |
| Material layer 3 | Gypsum board | 13 mm |

The data in the data model is often incomplete and/or contradictory, which is why the rules do not come close to 100% reliability. High reliability is important, especially when the classification is combined with 3D visualization of the data model—e.g. Incorrectly classified external or partition walls are easily noticeable visually.

In some embodiments of the inventive solution a set of “signals” describing the class of the building element is fed to the neural network, which then “weighs” them and predicts the class. In this way, it is possible to react to incomplete and/or conflicting data in the BIM. Artificial Intelligence Engine 828 generates probabilities for different classes, which are then transformed into a final class with the help of a scoring function. The “signals” going to the neural network 826 are the first level of bullet points in the previous paragraph (excluding the object ID).

In some embodiments, material layer set data has sub-levels that contain information that must be compiled first. Material layer set and Class hint are text-type data, so natural language processing methods and, more specifically, named entity recognition is preferably used.

In the case of Class hint information, the aim is to identify whether words describing the class of the Building element are present. Think of that as “class hint” information for a neural network. It strongly hints at what the outcome may be. The sentence vector of the material layer set is averaged from the word vectors of the Material layer data below it. The method has been chosen because it also produces vectors at the Material layer level, which information can also be utilised for another purpose—the classification of material layers.

Class hint vector and Material layer set vector act as inputs for a neural network engine 826 tasked with classifying a building element—e.g., a building element, whether it is an external or partition. In addition to vectors, other building element properties, such as Storey, BIM object class, Load bearing, External/Internal and Shape factor, act as inputs for the neural network 826.

A solution in which an AI model acts as an input for another AI model is called a stacked or blender model. As a result, the model produces probabilities for different classes, which are entered into a scoring function whose task is to convert probabilities into a single class. The scoring function in this case, and in general, uses rules to define the class, in most preferred embodiments.

An AI model trained for material layer vectors can also be used to classify material layer data. The model itself has been trained for just that thing, and the material layer vector is more of a by-product. The end result is building element class and material layer class data for the object. This data is a dimension of the data warehouse, which means that artificial intelligence enables the creation of a data warehouse.

As one can see, a lot revolves around the structural type and/or class of the building element and the materials. For Building space and element assembly, the data pair is the object name and materials. Training an AI model therefore requires a text containing such words.

For training the AI model in an exemplary inventive embodiment, I used sentences produced from data models in my possession, and I used a BIM envelope to generate them. The format of the sentences is presented below:
<BIM object class> <Material layer 1> <Material layer 2> etc.

The sentences I generate are not human-spoken text, but that is okay. Word2Vec compares the probability of word pairs occurring, and in that sense the text is very “efficient” because it lacks words that are irrelevant to this recognition task, such as verbs and adjectives.

I also wanted to include human-written text, but it should be about the same subject and preferably have the same style, i.e. truncated technical specifications. The solution turned out to be very easy, as quantity lists of old construction projects and construction cost databases, for example, contain the necessary kind of text, and there are many of them. In addition, some of them already have labels, because they follow the existing classifications of construction.

When creating a material layer vector, the invention preferably uses a model trained in the classification of material information, which produces a word vector for the text entered into it. For example, a template could be Word2Vec or fastText. The advantage of the latter is that instead of whole words, it deals with N-grams, that is, splits the letter N of words into long sections. Material information often contains abbreviations, so a method based on N-grams usually works better than, for example, a method based on Word2Vec.

The name of the material layer can contain one or several words, that is, it is analogous to a sentence, if not a sentence. Its words are entered one by one into the AI model, the word vectors of the words are temporarily stored, and after the last word, sentence vector is calculated for the sentence, which is obtained as the average of the word vectors without weighting. The vectors also ignore the order of the words, since there is no difference in the meaning of the phrases “insulation +aluminium frame” and “aluminium frame +insulation”.

In one embodiment a BIM envelope is used to train the AI model, but it could also be used in the inferring phase. In other words, at least BIM object class information would be added before the material layer name, which would be taken into account using the self-attention method familiar from Transformer. This feature could bring benefits in a situation where the name of the material layer is vague, i.e. “frame structure”. The word can mean different material depending on whether it is wall, slab, etc. object.

One inventive aspect creates a class hint vector. A vector is created like a material layer vector, but class hint information is used as the sentence and the model is trained to recognize classes in the building element.

One inventive aspect calculates a material layer set vector.

Material layer set is a sentence for which a value should be calculated from the material layer vectors underlying it. However, it cannot be calculated as an average alone, but the following factors should be considered.
The order of the layers of material (syntax: <layer 1>-<layer 2>-etc.)

$$“ plaster - insulation + aluminum - plaster ” is different to$$

$$“ plaster - plaster - insulation + aluminum ”$$

Thickness of material layers
   10 mm concrete is completely different from 500 mm concrete

The order of the material layers is taken into account by combining word vector with a position vector from transformer, which is a general-purpose tool. The end result is a position encoded material layer vector.

Finally, a sentence vector is formed for the material layer set as a weighted average of the position encoded material layer vectors. The thickness or net volume of the material layer is used as the weight of each layer, i.e. thickness x net area.

The end result is a material layer set vector that takes into account the order and thickness of the material layer.

In preferable embodiments of the invention the building element class is classified as follows: A specially trained stacked neural network (or just a model) is used for classification. The inputs in the stacked model are:
Class hint vector
Material layer set vector
Storey
BIM object class
Load bearing
External/Internal
Shape factor
etc.

The training data for this model is obtained from old data models, which only need to be labelled in one way or another—each object must be marked to indicate whether it is, for example, external or an internal partition. The data can be pre-labelled using rules and then a human can check the results. The process corresponds exactly to how BIMs are classified on a rule-based basis in construction projects.

The neural network produces the probabilities of the result for the classes, which are then fed into the scoring function and the end result is one class for the building element. However, the class can also be UNKNOWN.

In preferable embodiments of the invention Material layer class is determined as follows: The same model used to create material layer vectors is used for classification. In the same way, the model is entered with the name of the material layer, but instead of the vector, the model is asked for labels related to the text. Labels are the categories of materials in which the model was trained.

In response, the probabilities of the labels are obtained, which are entered into the scoring function. Its task is to convert the probabilities of labels to material layer class values.

In a simple case, one can select the label with the highest probability and check that the probability exceeds the lowest allowed value (threshold). If the highest value does not exceed threshold, then the value is set to UNKNOWN.

The scoring function must also be able to handle a situation where the material layer contains two or more different materials. This can be solved, for example, by having the Material layer class list include commonly used combinations, such as INSULATION_ALUMINIUM. The scoring function uses threshold as in a simple case, but it also includes rules-based logic to control several different materials. If it encounters a combination that is not listed in the listing, the value is set to UNKNOWN in some embodiments.

Any features of embodiment 80 may be readily combined or permuted with any of the other embodiments 10, 20, 30, 40, 50, 60, 70, 90, 91, 92, 93, 94, 95 and/or 96.

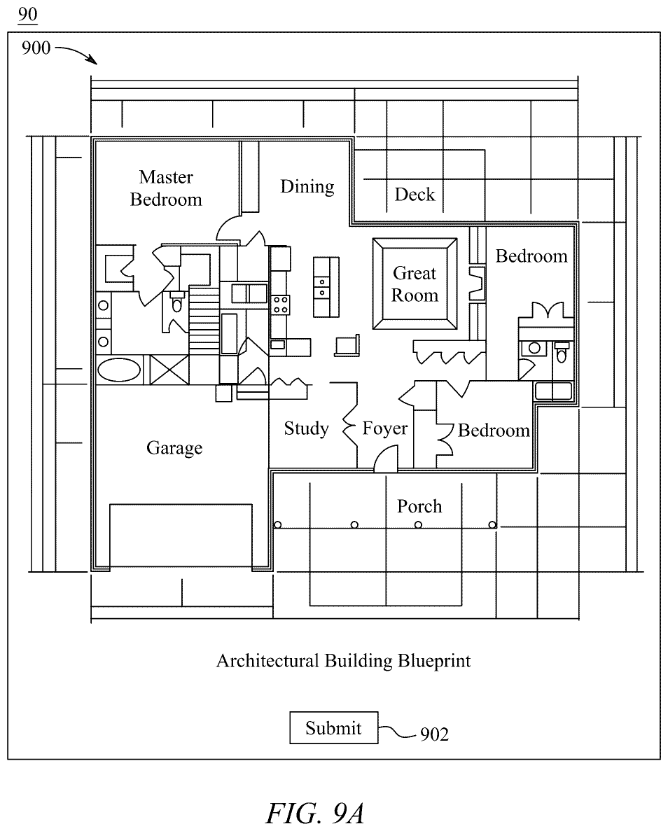

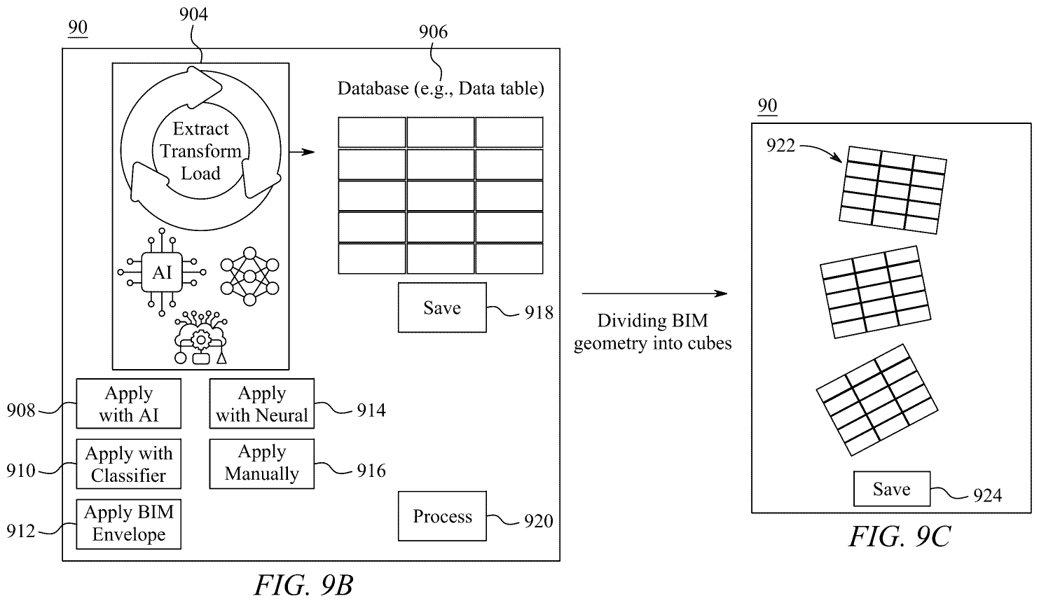

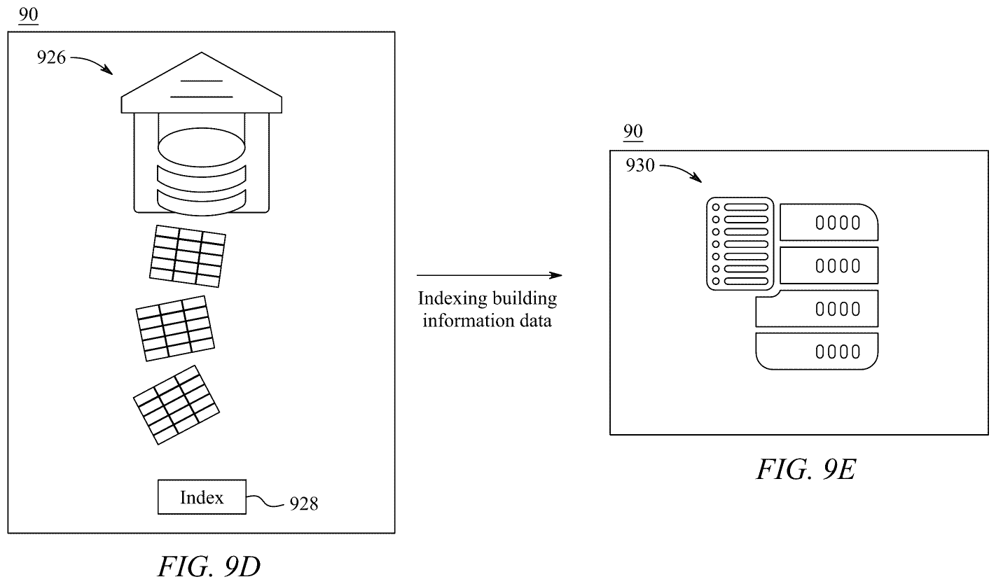

FIG. 9 demonstrates the software program embodiment 90, running in the system 80, in accordance with method 70. FIG. 9A shows the architectural blueprint as before, which has an underlying architectural BIM. FIG. 9b shows methodologies which can be used to process data in the BIMs. Typically, as a first step; the simplest ETL operations are performed using rule-based classification operations 910. In preferred embodiments as a second step, the ETL operations that could not be performed using said rule-based classification operations are performed using an artificial intelligence model or a neural network 908, 914. Also in some embodiments, a context word envelope is generated from the BIM (BIM envelope) to provide sufficient context information to the artificial intelligence model, and optionally said BIM envelope comprises parent-child and/or spatial relationships. A spatial relationship would mean for example that element A is joined to element B physically and spatially. A parent-child relationship would mean in this case the classical computing definition of a logical relationship; for example, a bathroom sink (parent) having to exist before the bathroom faucet (child) in said bathroom sink can exist.

As a third step, the ETL operations that are still uncompleted after the said first and second steps, are escalated to a human operator, who inputs the manually 916.

These three steps may take place in each of the ETL operations shown in FIGS. 9B-9E prior to indexing.

Any features of embodiment 90 may be readily combined or permuted with any of the other embodiments 10, 20, 30, 40, 50, 60, 70, 80, 91, 92, 93, 94, 95 and/or 96.

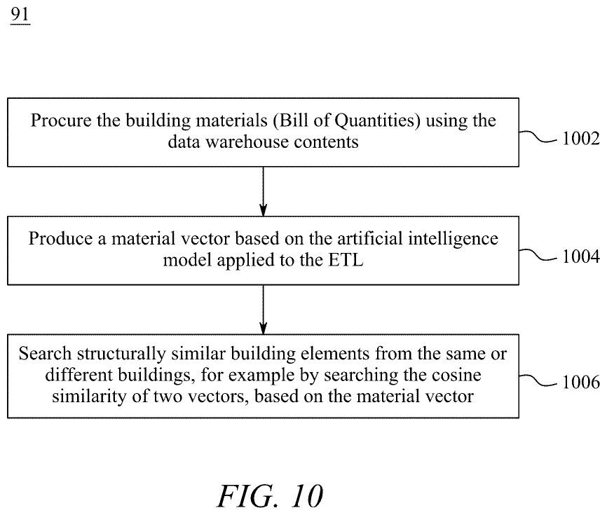

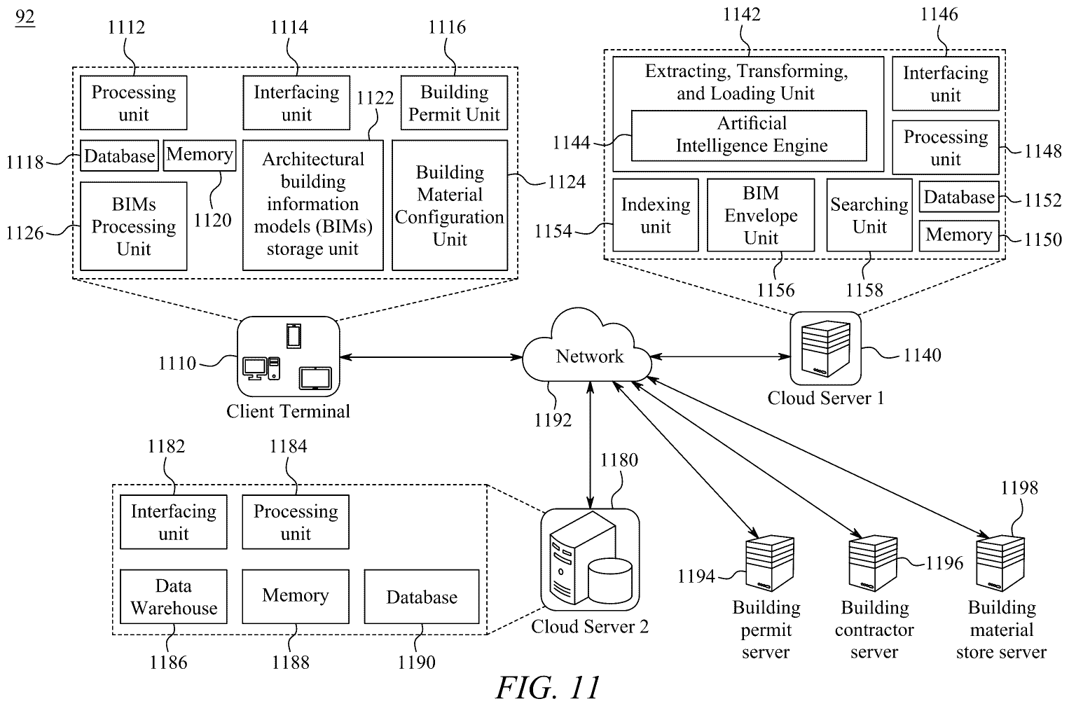

FIG. 10 describes an embodiment 91 of the invention where the data in the data warehouse is used to achieve different technical goals in the building construction process. That is, the data warehouse already contains the combined BIM data that has been divided into cubes, and the objects and the materials in that data have been indexed to be searchable.

Also, in phase 1002 it is possible that the building materials are procured using the data warehouse contents and Bill of Materials report. In preferred embodiments, different building material providers can be provided with credentials to access the data warehouse 856, and they may submit bids based on the identified material needs in the combined BIM. For example, a building material wholesaler could access the Bill of Materials report for a building project and prepare a quote for the materials and delivery of them on the building site. Upon approval of the quote, the delivery men of the building supplies wholesaler will deliver the materials to the correct floor and section of the building according to the delivery requests made by the customer. Customer's building crew can then simply assemble them to be a part, i.e. building element, of the building. This reduces the administrative and managerial overhead considerably and results in faster building at a lower cost.

In phase 1004 a material vector is produced. Based on the artificial intelligence model being applied to the ETL, and consistent nomenclature and units, all materials and objects should now be correctly indexed in the data warehouse. A material vector is a vector that defines a set of co-ordinates within the BIM, and the materials and objects located within that co-ordinate set.

Also, in a more sophisticated embodiment of phase 1004 may involve a feature vector is produced for BIM objects in the data warehouse. BIM object's feature vector is a vector that concatenates the material layer set vector with the values of other harmonized properties of the object, like but not limited to object class, load bearing and colour, into a single vector. The feature vectors can be used, for example, as an input to an artificial intelligence model predicting the cost of the building.

In phase 1006 based on the material vector, structurally similar building elements can be searched from the same or different buildings, for example by searching the cosine similarity of two vectors. For example, a building contractor might be hired to paint and refurbish an apartment that is located in 10 particular cubes. If the painting and refurbishment project is a success, which is desired to be repeated, identical sets of 10 cubes could be searched from the data warehouse. Then additional identical painting and refurbishment projects could be ordered from the same building contractor without the administrative hassle required in the defining of the painting and refurbishment project.

In one aspect of the invention a material vector is presented in text form, for example “{0,42; 0,17; 0,68; 0,82 etc.}”, can be used as unique “code” for a BIM objects, regardless of the building or project. For example, cost estimating applications used by the building contractors often have a feature, which enables to map an item in a Bill of Quantities to an item in the construction cost estimating application's construction cost database based on item code, name and the like or combination of these properties. The mapping might be based on, for example, synonym tables in the construction cost estimating application. Construction companies usually need to create these mappings from scratch for each project because the designers change in each project and every design company has their own way for coding and naming the BIM objects. Building and project independent coding, on the other hand, enables to create the mapping once, for example “{0,42; 0,17; 0,68; 0,82 etc.}” is mapped with cost database code “IW-03”, and to use it in the future projects, which saves a significant amount of time and effort for the construction company.

Any features of embodiment 91 may be readily combined or permuted with any of the other embodiments 10, 20, 30, 40, 50, 60, 70, 80, 90, 92, 93, 94, 95 and/or 96.

FIG. 11 shows the embodiment 92 of the cloud computing system executing the method of embodiment 91.

A building permit server 1194 is connected to the data warehouse 1186. The communication can be bi-directional, and in some embodiments the building permit server 1194 simply views the indexed data warehouse 1186. However, in almost all practical cases the most practicable solution for deciding and archiving of the building permit would be the retrieval of the data warehouse contents and/or the combined BIM to the building permit server. This way all details about the building plans, and the decision based on which the building permit is granted, can be electronically and cost-efficiently stored for a long time.

A building material store server 1198 is configured to connect to the data warehouse 1186 also. By accessing the data warehouse 1186 the building material store 1198 can get a picture of the building material demands of a particular project. Consequently, the building material store 1198 may provide quotes on building materials that are 100% relevant both in quantity and quality to the property developer developing the building described by the combined BIM. In some embodiments the property developer may send requests for quotes for producing a part of the building or the entire building to the store 1198 server. In some embodiments the Request for Quote is the entire Bill of Quantities of the building in the BIM. I.e. all materials required to produce the building are procured using the data warehouse 1186 contents.

A building contractor server 1196 may also be connected to the data warehouse 1186 in some embodiments. Via the connection the building contractor may acquire a material vector descriptive of the part of the building in the BIM the building contractor is supposed to build. The material vector is based on the artificial intelligence model being applied to the ETL so the nomenclature and units should be consistent. Based on the material vector, structurally similar building elements or parts of the building can be searched from the same or different buildings, for example by searching the cosine similarity of two vectors. Upon finding these similar or identical material vectors, the building contractor may seek to build these parts of the building in a similar or identical way. Thereby increasing the efficiency of the building process. Also, via the connection the building contractor may acquire a Bills of Quantities, Bills of Materials and feature vectors descriptive of the part of the building in the BIM the building contractor is supposed to build. The Bills of Quantities, Bills of Materials and feature vectors are based on the artificial intelligence model being applied to the ETL so the nomenclature and units should be consistent.

Any features of embodiment 92 may be readily combined or permuted with any of the other embodiments 10, 20, 30, 40, 50, 60, 70, 80, 90, 91, 93, 94, 95 and/or 96.

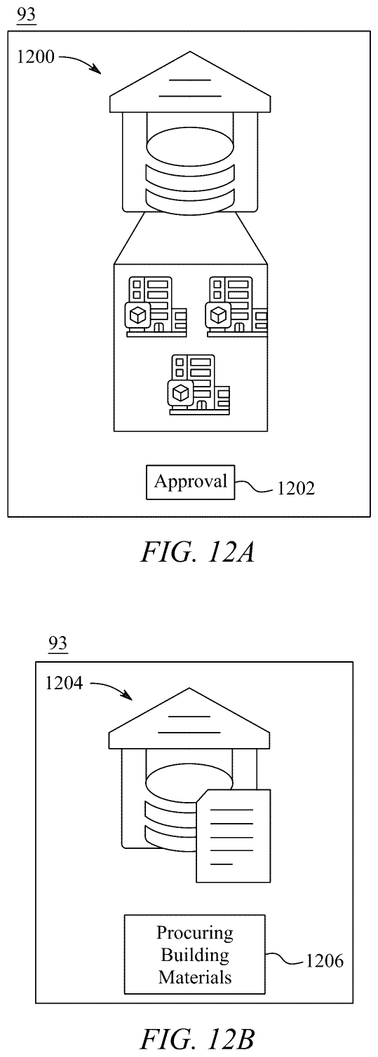

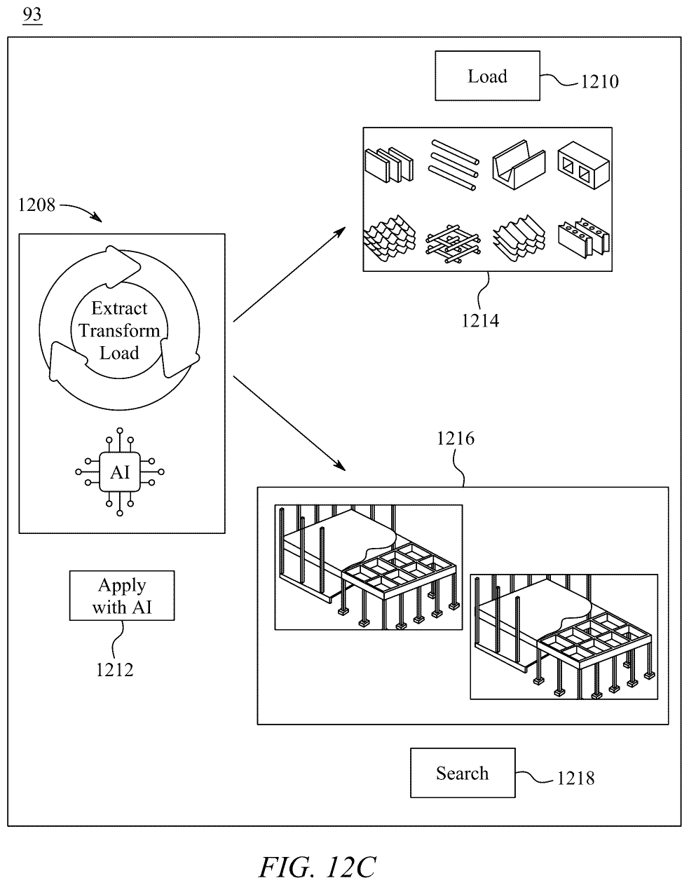

FIG. 12 shows an embodiment 93 of the software program product that operates the method 91 in the system 92. FIG. 12A shows the use case 1200 where a human user approves the contents of the data warehouse.

FIG. 12B shows the use case 1204 where the building materials (Bill of Quantities) are procured using the data warehouse 1186 contents from a store server 1198.

FIG. 12C shows the use case 1208 where, based on the artificial intelligence model being applied to the ETL, a material vector or feature vector is produced. The material vector lists the construction materials 1214 in a particular cube or in a particular location 1216. Based on the material vector, structurally similar building elements can be searched from the same or different buildings, for example by searching the cosine similarity of two vectors, in accordance with the invention in some embodiments.

Alternatively in FIG. 12C use case 1208, based on the artificial intelligence model being applied to the ETL, a feature vector is produced. The feature vector is a vector that concatenates the material layer set vector with the values of other harmonized properties of the object, like but not limited to object class, load bearing and colour, into a single vector. The feature vectors can be used, for example, as an input to an artificial intelligence model predicting the cost of the building.

Any features of embodiment 93 may be readily combined or permuted with any of the other embodiments 10, 20, 30, 40, 50, 60, 70, 80, 90, 91, 92, 94, 95 and/or 96.

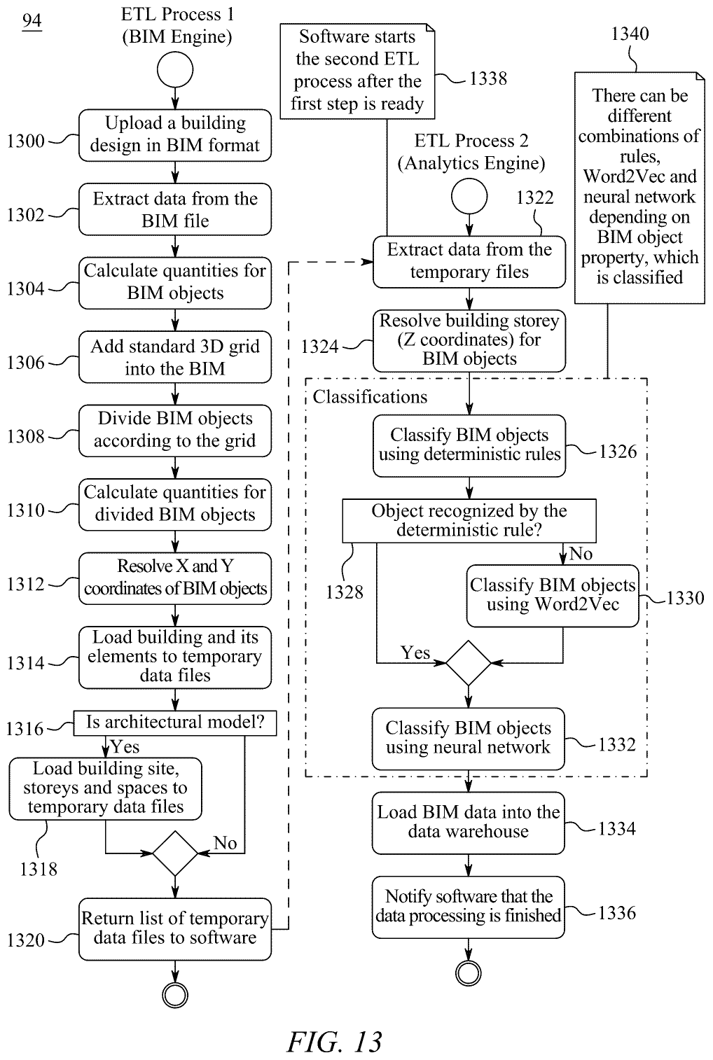

FIG. 13 shows an embodiment 94 of the best mode of implementing the inventive method. The first ETL process typically operates in the BIM software engine and goes as follows:
In phase 1300 a building design is uploaded in BIM format. The BIM software runs on Microsoft Azure in this embodiment, so the BIM files are uploaded to Microsoft Azure, and typically grouped in “containers” which approximately equate “folders” in the file system.

In phase 1302 data is extracted from the BIM file.

In phase 1304 quantities of building materials are calculated for BIM objects.

In phase 1306 a standard 3D grid is added into the BIM.

In phase 1308 BIM objects are divided according to the grid.

In phase 1310 quantities are calculated for divided BIM objects.

In phase 1312 X, Y coordinates of BIM objects are resolved.

In phase 1314 the building and its elements are loaded to temporary data files

In phase 1316 it is determined if the BIM is an architectural model or not.

If yes, the process moves to phase 1318 and loads the building site, storeys, and spaces to temporary data files.

If no, the process moves to phase 1320, and returns a list of temporary data files to software. This completes the first ETL process, after all BIMs have been uploaded.

After this the analytics engine completes the second ETL process, phase 1338, and moves to phase 1322.

In phase 1322 data is extracted from the temporary data files.

In phase 1324 building storey (Z coordinates) is resolved for the BIM objects.

In the event that different BIM files reference a different number of storeys, both deterministic calculation methods as well as AI can be used to convert all BIMs to use the correct number of storeys.

In phase 1326 BIM objects are classified using deterministic rules.

In phase 1328 it is determined if the object is recognized by the deterministic rule?

If yes, the process moves to phase 1332.

If no, in phase 1330 the BIM objects are classified using Word2Vec or some other AI model. Typically, also material layer sets are calculated by using an AI model that simulates the material layer set as if the individual layers were words, and the material layer set was a sentence in the best mode. This way the AI technology developed for semantic models can be readily leveraged to calculate floors, walls and ceilings correctly in the best mode of the invention.

Invention uses trained machine learning models, like Word2Vec or Doc2Vec, to produce word vectors or embeddings for BIM object property values and/or names. The models are trained using a large corpus of relevant texts, for example but not limited to, texts created from existing BIM data, bills of quantities and cost estimating databases.

Bills of quantities and cost estimating databases contain short sentences like “Int. wall gypsum-aluminium studs-gypsum 110 mm”. BIM data, on the other hand, can contain only a single word, like “gypsum” in case of BIM object's material layer name. Thus, context words need to be generated, if models like Word2Vec and Doc2Vec are to be used to produce the word vectors.

The context words are generated using the relationships between the objects in the building information model. For example, in case of an object's material layer name the context words could be values of the object type and external/internal properties making the sentence “wall internal gypsum”. If the object's storey is located below the ground level, then word “basement” could be added to the sentence. The context words can also envelope (BIM envelope) the target word “gypsum” making the sentence “wall internal gypsum basement”. The resulting BIM enveloped sentences are consistent with the corpus sentences coming from other sources making the corpus suitable for training the machine learning model. The role of the other sources is to broaden the vocabulary with words that do not exist in the BIMs used for the training.

Typically, multiple machine learning models would be trained, i.e. one for each data warehouse dimension, which uses word embeddings and/or named entity recognition for classification. In case of material layer names, the machine learning model would be trained with a corpus which is labelled according to desired material layer classes, like but not limited to gypsum, concrete, wood, aluminium and glass.

When transforming the BIM data, a piece of text, like material layer name, is sent to above-described machine learning model and it returns a list of probabilities for the text belonging to a class, for example Gypsym 0,89223. The resulting list class probabilities is called Material layer vector. The vector is next sent to a scoring function, which determines the final value for the class. The scoring function might, for example, select the class with the highest probability and the check, if the probability exceeds the minimum level of confidence required. If minimum level of confidence is exceeded, then the value will the class with highest probability and otherwise the value will be set to “Unknown”. The resulting class value will be written into the data warehouse either to separate data column or it can replace the existing value.

Classifying building elements into external walls, internal walls, slabs on ground, floor slabs, roofs and the like could be done using named entity recognition and, for example, building element's construction type property, but the results might not be satisfactory. The reason for this is that the BIM data is often incomplete and/or contradictory. Object's construction type might have a value “Default” and the classification result would be “Unknown”. On the other hand, the object's other properties might contain information, which enable to classify it correctly, for example, to “Internal Wall”.

In phase 1332 a neural network may try to classify the unclassified BIM objects. The recommended solution for complex classification cases like above is to use stacked or blender neural network. The inputs for the neural network might be, but not limited to, following BIM object properties:
Object type (wall, slab, window and the like)
Storey
Class hint
Material layer set vector
External/internal
Load bearing

Class hint is a preliminary classification based on, for example, object's construction type property value. Rule based synonym classifier, for example, could be used to recognize, if the value contains abbreviation “IW” hinting that the object might belong to “Internal walls” class. Alternative solution is to use named entity recognition to achieve the same result.

Object's Material layer set vector is formed based on word and/or sentence vectors of object's individual material layers. First step is to position encode the individual the vectors. The positions naturally come from the order of material layers in the BIM data. Next a weighted average is Position encoded vectors is calculated. Material layer thickness, for example, might be used as the weight when calculating the average. The resulting vector describes the “structural semantics” of the object in a format, which can be used, for example, as an input to a stacked or blender neural network.

The stacked or blender neural network is trained in a similar way than the model trained for word embeddings. Large corpus, which is labelled according to desired classes, in this case External wall, Internal wall, Slab on grade, Floor slab, Roof and the like, is used for the training. Existing BIMs are used to create the basis for the corpus and labelling is done by a human operator.

When transforming the BIM data, input values are sent to the machine learning model, and it returns a list of probabilities for the object belonging to a class. The resulting list of probabilities is next sent to a scoring function, which determines the final value for the class. The scoring function might, for example, select the class with the highest probability and the check, if the probability exceeds the minimum level of confidence required. If minimum level of confidence is exceeded, then the value will the class with highest probability and otherwise the value will be set to “Unknown”. The resulting class value will be written into the data warehouse either to separate data column or it can replace the existing value.

In phase 1334 BIM data is loaded into the data warehouse 1186. The data warehouse 1186 can be connected to different known analytics software products, such as Power BI, Qlik, Tableau, Microsoft Synapse. Some of these Business Intelligence software products can be used to convert the data warehouse contents into a relational database. Some of these Business Intelligence software products can be used to prepare reports of the building in the BIM. For example, financial reports regarding the profitability of the building can be generated in accordance with the invention by applying analytics software to the data warehouse 1186. For example, it may be predicted whether the building will be profitable or not, prior to commencing the construction of the building, or before purchasing any materials.

In phase 1336 it is notified by the software that the data processing is finished.

In phase 1340 for the yet unclassified BIM objects different combinations of rules, Word2Vec or neural network may be attempted, or the unclassified BIM objects are escalated to a human user, and human classification is sought from the user to the BIM object.

In some embodiments of the invention the improved data warehouse or a relational database housing the data warehouse contents can be used to improve the original BIM models. Due to the data integrity improving features of the different ETL stages, the original BIM models can likely be improved based on the data warehouse or database data.

Any features of embodiment 94 may be readily combined or permuted with any of the other embodiments 10, 20, 30, 40, 50, 60, 70, 80, 90, 91, 92, 93, 95 and/or 96.

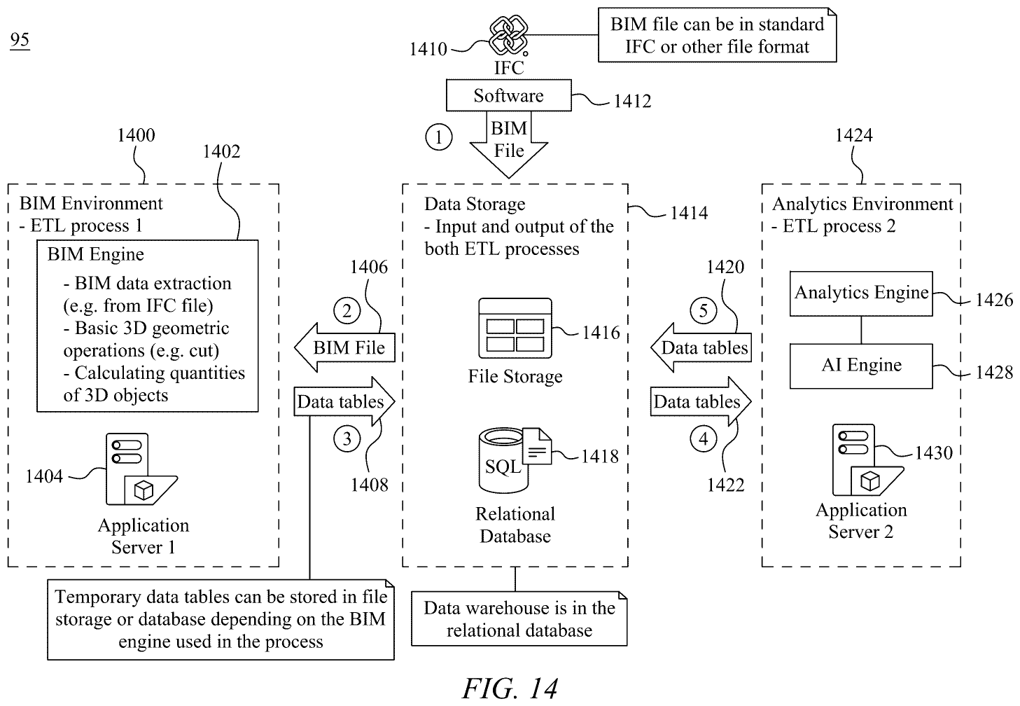

FIG. 14 shows an embodiment 95 of the computer system that implements the inventive method 94 in accordance with the best mode of the invention. The phases 1300-1320 are operated by the BIM engine 1400. The data files and data tables are stored in the Data storage 1414, typically in a relational database 1418 or in file storage 1416. The data warehouse 1186 is typically in a relational database 1418. Temporary data tables can be stored in file storage 1416 or database 1418 depending on the BIM engine used in the process.

The second ETL process, phases 1322-1340, is typically carried out by the Analytics Engine 1426 and the AI Engine 1428.

Any features of embodiment 95 may be readily combined or permuted with any of the other embodiments 10, 20, 30, 40, 50, 60, 70, 80, 90, 91, 92, 93, 94 and/or 96.

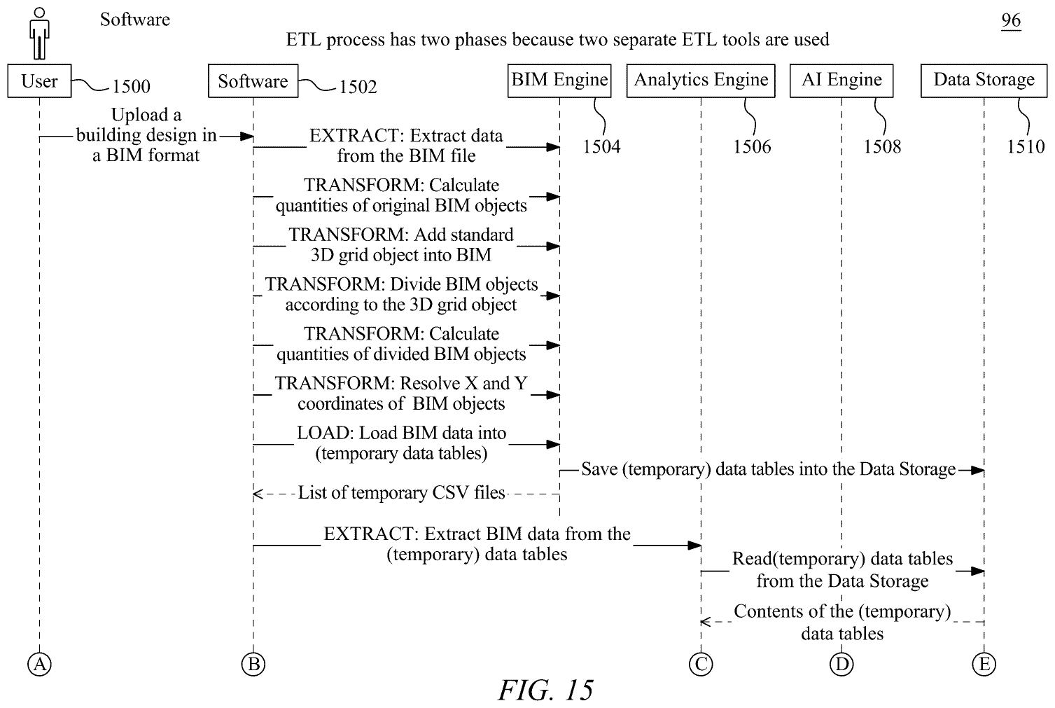

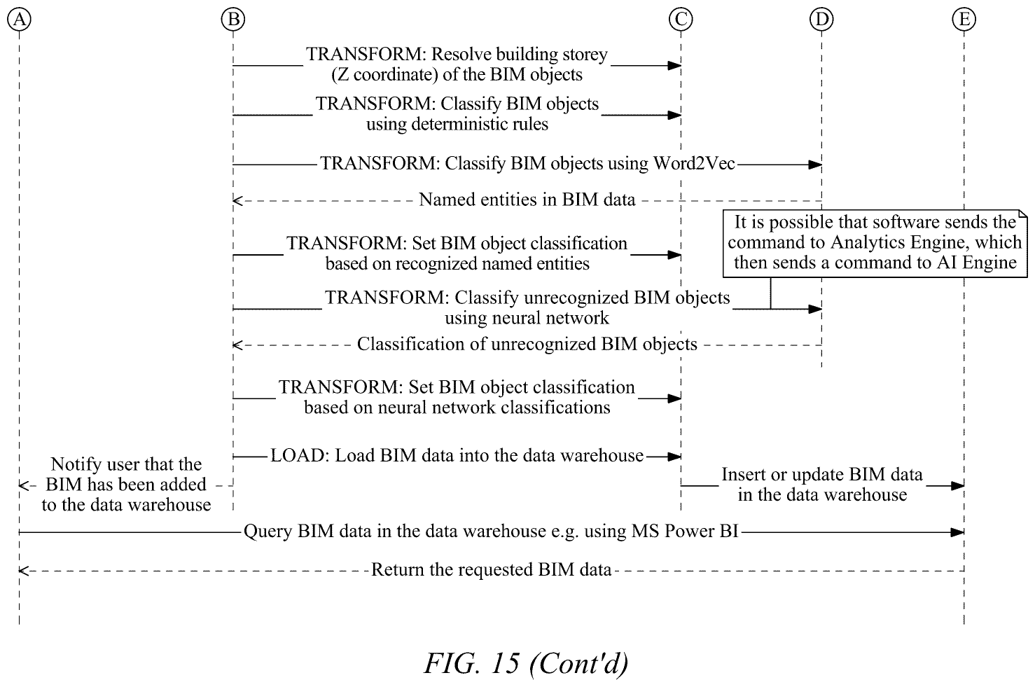

FIG. 15 shows an embodiment 96 of the software program product that runs in the system 95 and implements the method 94 in accordance with the best mode of the invention.

FIG. 15 page 22 shows the first ETL process in chart that signifies the type of the operation as “EXTRACT”, “TRANSFORM” or “LOAD”. The arrows designate the starting point and the end point of the operation. The method 94 operated in the system 95 is thus superposed on this chart 96. Page 23/23 shows the second ETL process in the same way.

Any features of embodiment 96 may be readily combined or permuted with any of the other embodiments 10, 20, 30, 40, 50, 60, 70, 80, 90, 91, 92, 93, 94 and/or 95.

Some phases may be executed concurrently, in parallel or in series. For example, the rule-based transformation and the AI based transformation may be implemented to work in parallel concurrently, or in series.

The invention has been explained above with reference to the aforementioned embodiments and several commercial and industrial advantages have been demonstrated. The methods and arrangements of the invention capture a physical building into the cloud. Once the complete BIM is captured in the cloud, the property development process can be streamlined and scaled, resulting in higher quality and lower cost buildings to consumers.

The invention allows the property developer of the building to manage multiple different teams from different areas of engineering to produce a high-quality building with a small administrative overhead. Furthermore, with experience each BIM can be further refined and reused in a different building site to produce a similar, but even better building. Additionally, the invention can be used to predict unprofitable projects. when a sufficiently detailed building information model is in the system, and the developer has an accounting software with accurate prices, the system can linearly project, or predict using AI, the cost of the building. Based on the predictions, the developer can avoid unprofitable projects early on, for example at the Request for Quote stage. These are substantial advantages that lead to higher quality and lower cost buildings to consumers from more reliable and credit worthy home builders in the marketplace.

The invention has been explained above with reference to the aforementioned embodiments. However, it is clear that the invention is not only restricted to these embodiments, but comprises all possible embodiments within the spirit and scope of the inventive thought and the following patent claims.

1. A method used in a computer system for managing building information, the method comprising:
extracting and loading a primary design discipline building information model (BIM) to data tables and/or data files,
extracting and loading one or more subsequent building information models for the building to data tables and/or data files respectively,
dividing the building information model object geometry into sections, resolving sections for the divided objects, and calculating quantities of the divided geometry,
from the data tables and/or data files, extracting, transforming, and loading the data to a data warehouse,
harmonizing building storey definitions in each subsequent building information model to match the primary design discipline building information model,
indexing building information object and quantity data in the data warehouse at least based on the building identifier, storey identifier, section identifier and/or material layer set vector.

2. A method as claimed in claim 1, wherein a deterministic rule-based synonym classifier is used in extracting, transforming and/or loading.

3. A method as claimed in claim 1, wherein an artificial intelligence model and/or neural network is used in extracting, transforming, and loading and material layer sets are calculated by using a semantic AI model that simulates the material layer set as if the individual layers were words, and the material layer set was a sentence.

4. A method as claimed in claim 1, wherein multiple building information models of different buildings are loaded into the same data warehouse.

5. A method as claimed in claim 1, wherein the first building model is an architectural building information model, and a subsequent second building information model is any of the following: electrical plan, ventilation plan, sewage plan, waterline plan, constructional plan.

6. A method as claimed in claim 1, wherein a building permit is obtained with the building information model and data warehouse.

7. A method as claimed in claim 1, wherein the building materials are procured using the data warehouse contents.

8. A method as claimed in claim 1, wherein:
in a first step; the simplest ETL operations are performed using rule-based classification operations,
in a second step; the ETL operations that could not be performed using said rule-based classification operations are performed using an artificial intelligence model or a neural network, and
in a third step; the ETL operations that are still uncompleted after the said first and second steps, are escalated to a human operator.

9. A method as claimed in claim 8, wherein a context word envelope is generated from a BIM envelope to provide sufficient context information to the artificial intelligence model, and said BIM envelope comprises parent-child and/or spatial relationships.

10. A method as claimed in claim 9, wherein:
based on the artificial intelligence model being applied to the ETL, a material vector and/or object class vector is produced, and
based on the material vector and/or object class vector, structurally similar building elements are searchable from the same or different buildings.

11. A system, comprising a computer arranged to perform:
extracting, and loading of a primary design discipline building information model (BIM) to data tables and/or data files,
the extracting and loading of one or more subsequent building information models for the building to staging data tables and/or data files respectively,
the building information model object geometry is configured to be divided into sections, section is configured to be resolved for divided objects and quantities of the divided geometry are arranged to be calculated,
from the data table and/or data file the data is configured to be extracted, transformed, and loaded to a data warehouse,
building storey definitions in each subsequent building information model are configured to be harmonized with the primary design discipline building information model,
indexing building information object and quantity data in the data warehouse at least based on the building identifier, storey identifier, section identifier and/or material layer set vector.

12. The system as claimed in claim 11, wherein a deterministic rule-based synonym classifier is used in extracting, transforming and/or loading and floor levels are calculated deterministically from the sea level for all building models of different contractors to determine common floor levels in the Z-coordinate.

13. The system as claimed in claim 11, wherein an artificial intelligence model and/or neural network is configured to be used in extracting, transforming, and loading and material layer sets are calculated by using a semantic AI model that simulates the material layer set as if the individual layers were words, and the material layer set was a sentence.

14. The system as claimed in claim 11, wherein multiple building information models of different buildings are configured to be loaded into the same data warehouse.

15. The system as claimed in claim 11, wherein the subsequent second building information model is any of the following: electrical plan, ventilation plan, sewage plan, waterline plan, constructional plan.

16. The system as claimed in claim 11, wherein a building permit is configured to be obtained with the building information model and data warehouse.

17. The system as claimed in claim 11, wherein the building materials are configured to be procured using the data warehouse contents.

18. The system as claimed in claim 11, wherein the system is configured to perform the following operations:
in a first step; the simplest ETL operations are performed using rule-based classification operations,
in a second step; the ETL operations that could not be performed using said rule-based classification operations are performed using an artificial intelligence model or a neural network, and/or
in a third step; the ETL operations that are still uncompleted after the said first and second steps, are escalated to a human operator.

19. The system as claimed in claim 18, wherein a context word envelope is generated from a BIM envelope to provide sufficient context information to the artificial intelligence model, and said BIM envelope comprises parent-child and/or spatial relationships.

20. The system as claimed in claim 19, wherein:
based on the artificial intelligence model being applied to the ETL, a material vector and/or object class vector is produced, and
based on the material vector and/or object class vector, structurally similar building elements can be searched from the same or different buildings.

21. A software program product stored in a memory medium configured to run in a computer system for managing building information, wherein, in executing the software program product, the computing system is arranged to perform an operation, comprising:
extracting and loading a primary design discipline building information model (BIM) for a building to staging data tables and/or data files,
extracting and loading one or more subsequent building information models for the building to data tables and/or data files respectively,
dividing the building information model object geometry into sections, resolving sections for the divided objects and calculating quantities of the divided geometry,
from the data tables and/or data files, extracting, transforming, and loading the data to a data warehouse,
harmonizing building storey definitions in each design discipline's building information model to match primary design discipline building information model,
indexing building information object and quantity data in the data warehouse at least based on the building identifier, storey identifier, section identifier and/or material layer set vector.

22. The software program product as claimed in claim 21, wherein a deterministic rule-based synonym classifier is used in extracting, transforming and/or loading, and floor levels are calculated deterministically from the sea level for all building models of different contractors to determine common floor levels in the Z-coordinate.

23. The software program product as claimed in claim 21, wherein an artificial intelligence model and/or neural network is used in extracting, transforming, and loading and material layer sets are calculated by using an AI model that simulates the material layer set as if the individual layers were words, and the material layer set was a sentence.

24. The software program product as claimed in claim 21, wherein multiple building information models of different buildings are loaded into the same data warehouse.

25. The software program product as claimed in claim 21, wherein the subsequent second building information model 904 is any of the following: electrical plan, ventilation plan, sewage plan, waterline plan, constructional plan.

26. The software program product as claimed in claim 21, wherein a building permit is obtained with the building information model and data warehouse.

27. The software program product as claimed in claim 21, wherein the building materials are procured using the data warehouse contents.

28. The software program product as claimed in claim 21, wherein, in performing the operation, the following steps are performed:
in a first step; the simplest ETL operations are performed using rule-based classification operations,
in a second step; the ETL operations that could not be performed using said rule-based classification operations are performed using an artificial intelligence model or a neural network, and/or
in a third step; the ETL operations that are still uncompleted after the said first and second steps, are escalated to a human operator.

29. The software program product as claimed in claim 28, wherein a context word envelope is generated from a BIM envelope to provide sufficient context information to the artificial intelligence model, and said BIM envelope comprises parent-child and/or spatial relationships.

30. The software program product as claimed in claim 29, wherein:
based on the artificial intelligence model being applied to the ETL, a material vector and/or object class vector is produced, and
based on the material vector and/or object class vector, structurally similar building elements are searchable from the same or different buildings.
